(19) United States
(12) Patent Application Publication
(10) Pub. No.: US 2024/0220273 A1
(43) Pub. Date: Jul. 4, 2024

(54) HARDWARE ARCHITECTURE AND AN INSTRUCTION SET ARCHITECTURE FOR MACHINE-LEARNING COMPUTATIONS

(71) Applicant: Meta Platforms Technologies, LLC, Menlo Park, CA (US)

(72) Inventors: Vignesh Vivekraja, Santa Clara, CA (US); Tomonari Tohara, Sunnyvale, CA (US); Reza Tusi, San Jose, CA (US); Abuduwaili Tuoheti, San Jose, CA (US); Javid Jaffari, San Diego, CA (US); Vlad Fruchter, Los Altos, CA (US); David Vakrat, Kfar Saba (IL); Ohad Meitav, Sunnyvale, CA (US)

(21) Appl. No.: 18/527,004

(22) Filed: Dec. 1, 2023

Related U.S. Application Data
(60) Provisional application No. 63/477,527, filed on Dec. 28, 2022.

(51) Int. Cl. G06F 9/38; G06F 9/30

(52) U.S. Cl. CPC G06F 9/3893; G06F 9/3001; G06F 9/3012

(57) ABSTRACT

In one embodiment, a system comprising a processor and a non-transitory memory coupled to the processor comprising instructions executable by the processor. The processor, comprising an internal memory; a Multiply-Accumulate (MAC) array; a first vector register array; a second vector register array; and a third vector register array, is operable when executing a first instruction among the instructions to feed a weight vector array from the second vector register array to the MAC array, broadcast an input activation vector to the MAC array, multiply an input activation value broadcast to the MAC unit from the input activation vector and a weight value fed to the MAC unit from the weight vector array at each MAC unit in the MAC array, and store a partial output activation vector to the third vector register array, wherein the partial output activation vector is the output of the MAC array.

### PRIORITY

This application claims the benefit under 35 U.S.C. § 119(e) of U.S. Provisional Patent Application No. 63/477,527, filed 28 Dec. 2022, which is incorporated herein by reference.

### TECHNICAL FIELD

This disclosure generally relates to hardware architecture and, more particularly, to a processor architecture for machine-learning computations.

### BACKGROUND

Neural networks are increasingly being used to implement machine learning (ML) techniques to solve a wide variety of problems including, but not limited to, object identification, feature classification, or content-driven image processing. Some neural networks, which may be referred to as convolutional neural networks, include one or more convolutional layers. In a convolutional neural network (CNN), the convolutional layers typically account for the vast majority of the computations performed and the data movement within the CNN and/or between the CNN and other elements of an ML model, making them a performance bottleneck. Existing ML accelerators focus on using high compute parallelism along with an optimized data orchestration throughout the memory hierarchy to speed up the processing of convolutional layers. However, existing ML accelerators may not perform well when implemented within edge devices that have strict power consumption constraints and that run inference exercises using previously trained models in real time. For example, existing ML accelerators may not perform well within artificial reality systems for virtual reality (VR), augmented reality (AR), mixed reality (MR), or hybrid reality implemented on standalone head-mounted displays (e.g., on AR/VR headsets), mobile devices or other edge computing devices.

### SUMMARY OF PARTICULAR EMBODIMENTS

In particular embodiments, a system may comprise at least a processor and an external memory coupled to the processor. The external memory may be a non-transitory memory. The processor may comprise an internal memory, a Multiply-Accumulate (MAC) array, a first vector register array communicatively connected to the MAC array through a multiplexer (MUX), a second vector register array communicatively connected to the MAC array, and a third vector register array communicatively connected to the MAC array. The non-transitory memory may comprise instructions executable by the processor. In particular embodiments, the processor may be a very large instruction word (VLIW) processor comprising a plurality of function units. The instructions may be performed simultaneously in the plurality of function units. In particular embodiments, an instruction set architecture (ISA) of the processor may support hardware instructions associated with hardware components of the processor including the internal memory, the MAC array, the first vector register array, the second vector register array, and the third vector register array. In particular embodiments, the instructions are single instruction multiple data (SIMD) instructions, each of which may process a fixed-size vector data.

In particular embodiments, the processor may configure one or more banks of the internal memory with configuration information including one or more bank sizes and one or more alignment sizes. The processor may allocate buffers within the internal memory for input activation tensor, output activation tensor, weights, or biases.

In particular embodiments, the processor may transfer weights for M filters and an input activation tensor from an external memory to the internal memory. In particular embodiments, the processor may insert paddings to the input activation tensor in the internal memory based on first configuration parameters. The first configuration parameters may be determined based at least on an activation tensor width, an activation tensor height, an output activation tensor width, an output activation tensor height, and a stride. The paddings may increase width or height of the input activation tensor. To insert the paddings to the activation tensor, the processor may allocate a second memory space for an activation matrix corresponding to each channel of the activation tensor along with a configured-number of paddings in the internal memory. The processor may initialize the configured-number of paddings in the second memory space. Then, the processor may copy data for each row of the activation matrix from a first memory space to a respective memory chunk in the second memory space. In the first memory space, the activation matrix may be stored in a sequence.

In particular embodiments, a shape of the MAC array may be dynamically configured at runtime to a required shape for convolution operations based on hardware configuration parameters stored in a register array designated for the hardware configuration parameters. The hardware configuration parameters may be determined based at least on C, a number of input channel, and M, a number of filters used for the convolution operations. In particular embodiments, the shape of the MAC array may be configured to C-by-M. An output activation tensor generated as a result of the convolution operations may have M channels. In particular embodiments, possible combinations of C and M may include (64, 8), (32, 16), or (16, 32).

In particular embodiments, the processor may perform convolution operations between an input activation tensor and M filters to generate an output activation tensor. To generate the output activation tensor, the processor may calculate each row e of the output activation tensor of the convolution operations by performing the convolution operations on corresponding R rows {h₀^{e}, . . . , h_{R-1}^{e}} of the input activation tensor with the M filters, where R is a filter height. The processor may calculate the output activation tensor row-by-row. A pixel element on row e of the output activation tensor may comprise M channels. To calculate row e of the output activation tensor, the processor may calculate multiplications for each row r among R rows of the filters. For calculating multiplications of weight elements in row r of the filters to generate row e of the output activation tensor, the processor may first determine that row hᵣ^{e} of the input activation tensor that corresponds to row r of the filters for calculating row e of the output activation tensor by=e×U_{y}+r, where U_{y} is a vertical stride for the convolution operations, and where e, hᵣ^{e}, and r are zero-based indices. For each column s, where s begins at zero, of the filters, the processor may optimize convolution operations between a filter element at coordinates (r, s) from each of the M filters and valid pixel elements in row hᵣ^{e} of the input activation tensor. For the optimized convolution operations, the processor may load P pixel elements starting from pixel element s of row hᵣ^{e} of the input activation tensor to the first vector register array, where P=W-S+1, where W is an input tensor width, and S is a filter width. Each pixel element may comprise an input activation vector of size C. In particular embodiments, the processor may be operable when executing a first instruction among the instructions in the external memory. The first instruction, a SIMD instruction, may cause the processor to load an input activation vector from the internal memory to a vector register indicated by the first instruction among the first vector register array. The input activation vector may comprise C input activation values corresponding to a pixel element within an input activation tensor, where C is a number of input channels. A source location of the input activation vector in the internal memory may be indicated by the first instruction. The processor may execute the instruction a number of times with different parameters to load P pixel elements starting from pixel element s of row hᵣ^{e} of the input activation tensor to the first vector register array.

In particular embodiments, for the optimized convolution operations between filter elements at coordinates (r, s) from the M filters and valid pixel elements in row hᵣ^{e} of the input activation tensor, the processor may load a filter element at coordinates (r, s) from each of the M filters to the second vector register array. Each filter element may comprise a weight vector of size C. Each of M weight vectors in the weight vector array may comprise C weight values. The weight vector array may comprise a filter element at a position of M filters. The processor may execute the second instruction a number of times with various parameters to load filter elements at coordinates (r, s) of the M filters.

In particular embodiments, the processor may be further operable to execute a third instruction among the instructions. The third instruction, a single SIMD instruction, may cause the processor to feed a weight vector array from the second vector register array to the MAC array. The third instruction may also cause the processor to broadcast an input activation vector to the MAC array. The input activation vector may be selected by the MUX from the first vector register array based on the third instruction. The third instruction may further cause the processor to multiply an input activation value broadcast to each MAC unit of the MAC array from the input activation vector and a weight value fed to the MAC unit from the weight vector array. The third instruction may cause the processor to generate a partial output activation value for each of the M filters by accumulating outputs of MAC units corresponding to the filter. A partial output activation vector may comprise M partial output activation values. The third instruction may further cause the processor to store the partial output activation vector to a vector register of the third vector register array. The storing may be an overwriting residual values of the vector register with values of the partial output activation vector or an accumulating the values of the partial output activation vector to the residual values of the vector register.

In particular embodiments, the processor may calculate a partial output activation vector for each valid pixel element k among the P pixel elements in the first vector register array by executing the third instruction, where the valid pixel element k at an iteration l is determined as k=l*Uₓ, where Uₓ is a horizontal stride for the convolution operations, wherein P=W−S+1, and where k and l are zero-based indices. For calculating a partial output activation vector, the processor may: (a) perform M*C element-wise multiplications between the pixel element k and the filter element at coordinates (r, s) of M filters; (b) generate a partial output activation vector having M output channels by summing results of multiplications belonging to a respective filter; and (c) accumulate the partial output activation vector to a corresponding vector register among the third vector register array. To perform M*C element-wise multiplications between the pixel element k and the filter element at coordinates (r, s) of M filters, the processor may feed M weight vectors in the second vector register array to a corresponding column of the MAC array. Each of the M weight vectors may be a filter element at coordinates (r, s) from respective filter among the M filters. Then, the processor may broadcast an input activation vector in the first vector register array to columns of the MAC matrix. The input activation vector may correspond to the pixel element k among the W−S+1 pixel elements in the first vector register array. The MUX may select a vector register containing the pixel element k among the first vector register array containing the W−S+1 pixel elements. Finally, the processor may perform a multiplication at each MAC unit in the MAC matrix between a respective activation value of the pixel element k corresponding to a channel and a respective weight value of the filter element at coordinates (r, s) corresponding to the channel from one of the M filters.

In particular embodiments, the processor may be further operable when executing a fourth instruction among the instructions. The fourth instruction may cause the processor to quantize n-bit numbers in a vector register among the third vector register array to m-bit numbers based on quantization parameters stored in a corresponding vector register designated for the quantization parameters. The fourth instruction may further cause the processor to perform a non-linear operation on the quantized m-bit numbers. In particular embodiments, the n-bit numbers may be 32-bit numbers. In particular embodiments, m may be 8, 16, or 32. In particular embodiments, the processor may perform quantization operations on the third vector register array based on quantization parameters by executing the fourth instruction. A quantization operation comprises a non-linear activation operation. Parameters associated with the non-linear activation operation may be in the quantization parameters stored in the corresponding vector register. The quantization operation may further comprise adding a bias. Parameters associated with the bias may be stored in a corresponding vector register. The third vector register array may comprise 32-bit elements. Quantization may quantize the 32-bit numbers in the third vector register array into 8-, 16-, or 32-bit numbers. In particular embodiments, the processor may store row e of the output activation tensor in the third vector register array to the internal memory.

The embodiments disclosed herein are only examples, and the scope of this disclosure is not limited to them. Particular embodiments may include all, some, or none of the components, elements, functions, operations, or steps of the embodiments disclosed above. Embodiments according to the invention are in particular disclosed in the attached claims directed to a method, a storage medium, a system and a computer program product, wherein any element mentioned in one claim category, e.g., method, can be claimed in another claim category, e.g., system, as well. The dependencies or references back in the attached claims are chosen for formal reasons only. However, any subject matter resulting from a deliberate reference back to any previous claims (in particular multiple dependencies) can be claimed as well, so that any combination of claims and the elements thereof are disclosed and can be claimed regardless of the dependencies chosen in the attached claims. The subject-matter which can be claimed comprises not only the combinations of elements as set out in the attached claims but also any other combination of elements in the claims, wherein each element mentioned in the claims can be combined with any other element or combination of other elements in the claims. Furthermore, any of the embodiments and elements thereof described or depicted herein can be claimed in a separate claim and/or in any combination with any embodiment or element described or depicted herein or with any of the elements of the attached claims.

Embodiments of the invention may include or be implemented in conjunction with an artificial reality system. Artificial reality is a form of reality that has been adjusted in some manner before presentation to a user, which may include, e.g., a virtual reality (VR), an augmented reality (AR), a mixed reality (MR), a hybrid reality, or some combination and/or derivatives thereof. Artificial reality content may include completely generated content or generated content combined with captured content (e.g., real-world photographs). The artificial reality content may include video, audio, haptic feedback, or some combination thereof, and any of which may be presented in a single channel or in multiple channels (such as stereo video that produces a three-dimensional effect to the viewer). Additionally, in some embodiments, artificial reality may be associated with applications, products, accessories, services, or some combination thereof, that are, e.g., used to create content in an artificial reality and/or used in (e.g., perform activities in) an artificial reality. The artificial reality system that provides the artificial reality content may be implemented on various platforms, including a head-mounted display (HMD) connected to a host computer system, a standalone HMD, a mobile device or computing system, or any other hardware platform capable of providing artificial reality content to one or more viewers.

### BRIEF DESCRIPTION OF THE DRAWINGS

FIG. 1A illustrates selected elements of an example convolutional layer in a convolutional neural network (CNN).

FIG. 1B illustrates example calculations to perform convolutions.

FIG. 1C illustrates an example pseudo code for convolutions between an activation tensor and filters.

FIG. 2A illustrates an example architecture of a typical VLIW.

FIG. 2B illustrates an example operations of an SIMD instruction.

FIG. 3 illustrates an example comparison of two ML acceleration approaches.

FIG. 4 illustrates an example processor architecture with additional hardware components for ML accelerations.

FIG. 5 illustrates an example data-flow for implementing the convolution operation.

FIG. 6 illustrates an example microarchitecture of the ML extensions for convolution acceleration.

FIG. 7 illustrates an example CNN computation using the ML extensions.

FIG. 8 illustrates an example operation sequence to compute convolution between an input activation tensor and M filters.

FIG. 9A illustrates an example illustration of a 3×3 convolution between a 34×34×16 input activation tensor and a 3×3×16 filter.

FIG. 9B illustrates an example row of an input activation tensor loaded to first vector registers to be multiplied with a filter element at column 0.

FIG. 9C illustrates an example row of an input activation tensor loaded to second vector registers to be multiplied with a filter element at column 1.

FIG. 9D illustrates an example row of an input activation tensor loaded to third vector registers to be multiplied with a filter element at column 2.

FIG. 10 illustrates an example method for performing a series of operations associated with convolution by executing a single instruction.

FIG. 11 illustrates an example method 1100 for generating an output activation tensor by performing convolution operations on an input activation tensor with M filter.

FIG. 12 illustrates example depth-wise convolutions.

FIGS. 13A-13B illustrate example routing of data for 2 lanes of the MAC array for depth-wise convolutions during phase 1 and phase2.

FIGS. 14A-14B illustrates example DW convolution operations for a RXS=3×3 with stride=1 during phase 1 and phase 2.

FIG. 15 illustrates an example MAC array optimized to handle 3×3 (RXS) convolutions with C=1.

FIG. 16 illustrates an example group-wise convolution with 2 filter groups.

FIG. 17 illustrates an example MAC array that are fractured into smaller sub-arrays.

FIG. 18 illustrates a list of example group configurations that can be supported by a MAC array with 512 MAC units.

FIG. 19 illustrates an example table illustrating sparse tensor encodings.

FIG. 20 illustrates an example hardware architecture optimization to support a structured sparse matrix multiplication acceleration.

FIG. 21 illustrates an example architecture diagram of a sparse MUX array for 2:1 sparse weight tensor.

FIG. 22 illustrates an example computer system.

### DESCRIPTION OF EXAMPLE EMBODIMENTS

Before discussing the present embodiments in detail, it may be beneficial to first provide some background information regarding neural networks and machine learning (ML) models in general. Machine-learning techniques have been used in a number of domains such as computer vision, natural language processing, video context understanding, self-driving cars, etc. Neural Networks (NN)/Deep Learning (DL) algorithms are the most popular and are the focus of this disclosure. These algorithms learn from massive datasets during a compute intensive process called training, by repeatedly adjusting parameters of the NN (Weights and Bias) to minimize the error between a NN output and a pre-recorded ground-truth. Once training is complete, these network parameters are fixed and deployed in the real world called inference. The focus of this disclosure is on inference use-cases, but many of the disclosures may be applied to training as well.

Convolution Neural Networks (CNNs) are a class of NNs used popularly in computer vision and image processing. A CNN may constitute a stack of convolutional layers followed by a non-linear function like a rectified linear unit (ReLU), a leaky-ReLU, Sigmoid, etc., which may be grouped together as a singular block. A CNN may also consist of other operators such as pooling, fully-connected (FC) layers to change the dimensionality of intermediate data and a SoftMax layer to normalize the outputs to a probability distribution. These components are stacked in different combinations to represent unique NN architectures. Networks have high learning-capacity/representative-power roughly proportional to the compute complexity, which may be measured by a number of multiply-accumulate operations and the number of parameters. Typically, convolutional layers, FC layers are the most compute intensive and benefit significantly with hardware acceleration.

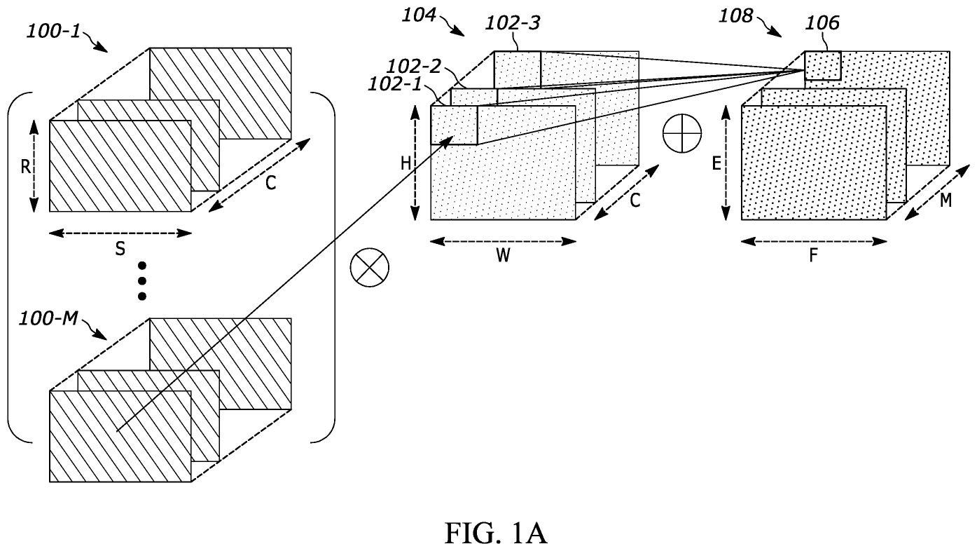

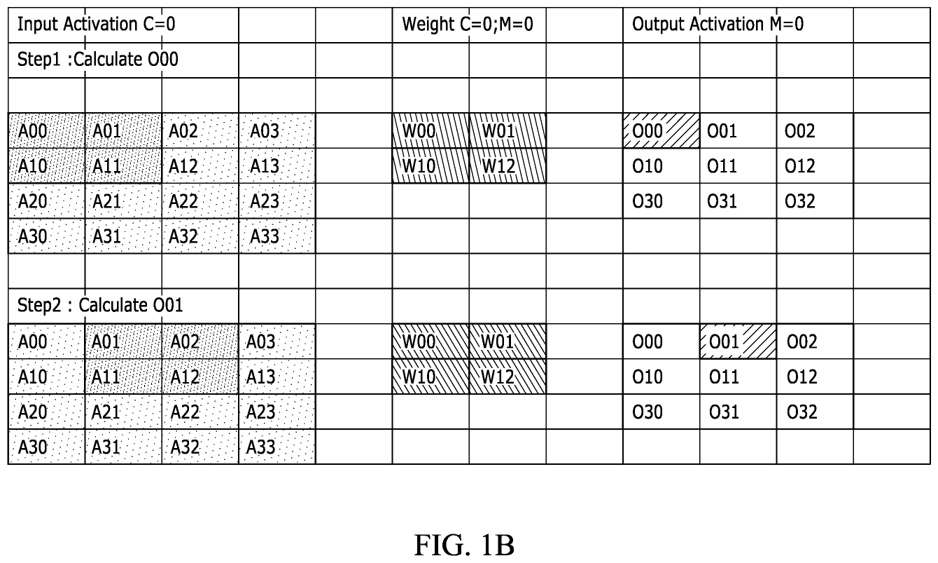

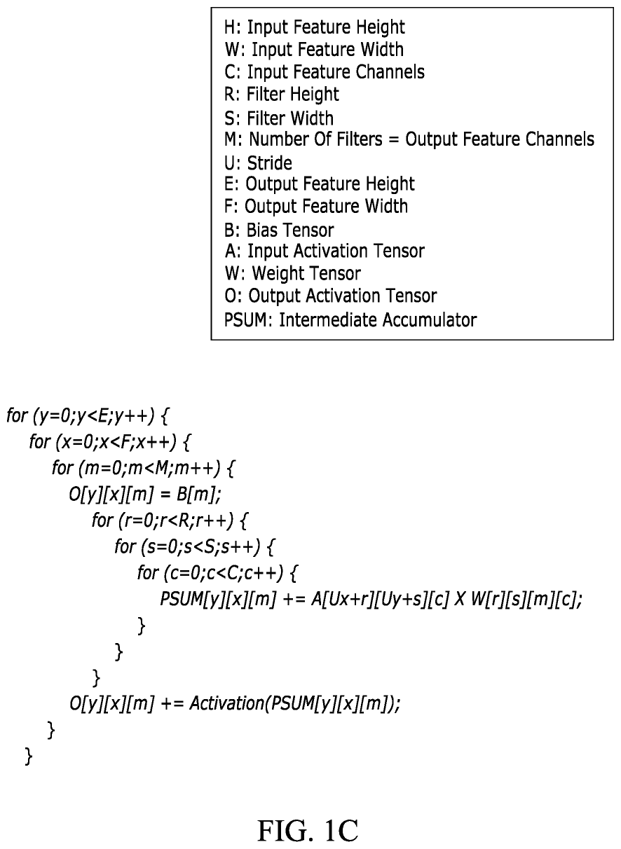

FIG. 1A illustrates selected elements of an example convolutional layer in a convolutional neural network. In the illustrated example, a three-dimensional (3D) output activation tensor 108 is generated by performing a series of two-dimensional (2D) convolution operations over a 3D input activation tensor 104 using a collection of 2D convolution kernels 100. More specifically, the input activation tensor 104 has dimensions H (height)×W (width)×C (where C represents a number of input channels) and the output activation tensor 108 has dimensions E×F×M (where M represents a number of output channels). In this example, multiple kernels 100 are to be applied to the input activation tensor to generate each element, of each channel, of the output activation tensor. More specifically, a respective different kernel 100 is applied to produce the elements of the output activation tensor for each given output channel. Therefore, the number of kernels 100 (i.e., M) matches the number of output channels (M).

As shown in FIG. 1A, each 3D filter 100 includes a respective 2D kernel of dimensions R×S for each input channel C, and each 2D filter kernel defines a collection of weights, where a respective weight value is associated with each filter element, as identified by its position within the R×S kernel. For example, each 2D filter kernel may be represented as a 3×3 grid of weights to be convolved with a similarly-sized collection of pixel elements within input activation tensor 104. More specifically, each 2D kernel of filter 100-M is applied in a convolution operation over the elements in a respective channel of input activation tensor 104. For example, a first 2D kernel of filter 100-M provides the weights that are multiplied by respective values of the elements in an R×S sized portion 102-1 of the elements of a first channel of input activation tensor 104, a second 2D kernel of filter 100-M provides the weights that are multiplied by respective values of the elements in an R×S sized portion 102-2 of the elements of a second channel of input activation tensor 104, and so on, such that a final 2D kernel of filter 300-M provides the weights that are multiplied by respective values of the elements in an R×S sized portion 102-3 of the elements of the last channel of input activation tensor 104. The results of these multiplication operations are then combined to generate a single element 106 of a single channel of output activation tensor 108, as shown in FIG. 1A. This process is repeated as the 2D kernels of filter 100-M are applied to other portions of input activation tensor 104 to produce the remaining elements of output activation tensor 108 in the same output channel as element 106, and as the 2D kernels of respective other ones of the filters 100 are applied to input activation tensor 104 to produce the elements of output activation tensor 108 in each of the remaining output channels.

FIG. 1B illustrates example calculations to perform convolutions. In the example illustrated in FIG. 1B, the input activation tensor is of size 4×4, with C input channels. Filters are of size 2×2, stride=1 with C input and M output channels. For brevity, FIG. 1B shows the operator being performed on each input channel and 1 output channel. In step 1, the 4 weights (W00,W01,W10,W12) are overlapped with 4 corresponding input activations (A00,A01,A10,A11) to calculate the first outputs O00 using the following dot product equation O00=A00*W00+A10*W10+A01*W01+A11*W12. In step 2, Now the weights are shifted by 1 entry to the right to produce O01 by O01=A01*W00+A02*W01+A11*W10+A12*W12. The steps are repeated across the entire input along the spatial axis to produce the output activation tensor for each input channel and output channel. The operation is repeated and accumulated across all C input channels to produce the output for 1 output channel. Further, convolution is repeated across M filters to produce the 3D output tensor.

FIG. 1C illustrates an example pseudo code for convolutions between an input activation tensor and filters. A shape of the input activation tensor is H×W×C, where H is an input activation height, W is an input activation width, and C is a number of input channels. A shape of an output activation tensor is E×F×M, wherein E is an output activation height, F is an output activation width, and M is a number of 3D filters. In the pseudo code illustrated in FIG. 1C, the filters are stored in 4D tensor, whose shape is R×S×M×C. A shape of an intermediate accumulator is identical to the shape of the output activation tensor, which is E×F×M. Biases are stored in an array size of M.

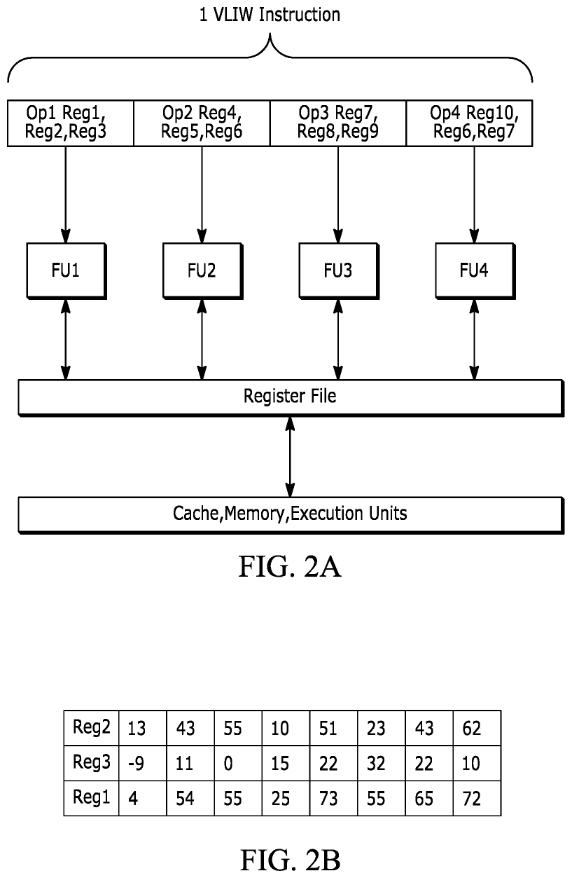

A Very Long Instruction Word (VLIW) processor may issue and complete more than one operation at a time. In the VLIW processors, the long instruction word encodes concurrent operations, resulting in dramatically reduced hardware complexity. A typical VLIW processor has multiple function units and multiple independent operations are grouped together to form a single VLIW instruction. These operations are initialized in the same clock cycle and each operation is dispatched to an independent function unit. All the function units share the same register file. FIG. 2A illustrates an example architecture of a typical VLIW. A compiler does the instruction scheduling and parallel dispatch of the word statically. The compiler also checks dependencies before scheduling a parallel execution of instructions. An example of a VLIW command may be {add reg1, reg1, reg2; ld reg7, reg3,offset; st reg4, reg5;sub reg6, reg6, 1}. This VLIW command contains 4 operations, 1) add 2) load 3) store 4) subtraction and all these 4 operations are initiated in the same clock cycle.

Single Instruction Multiple Data (SIMD) is for cases where a single instruction operates on multiple data simultaneously. A typical example of an SIMD instruction may be:

add reg1,reg2,reg3

In this example, reg1, reg2 and reg3 are vectors that contain 8-bit integer type values and each contain 8 elements. The add instruction operates on all 8 elements of reg2 and reg3 and stores the 8 output values into reg1. FIG. 2B illustrates an example operations of an SIMD instruction discussed above.

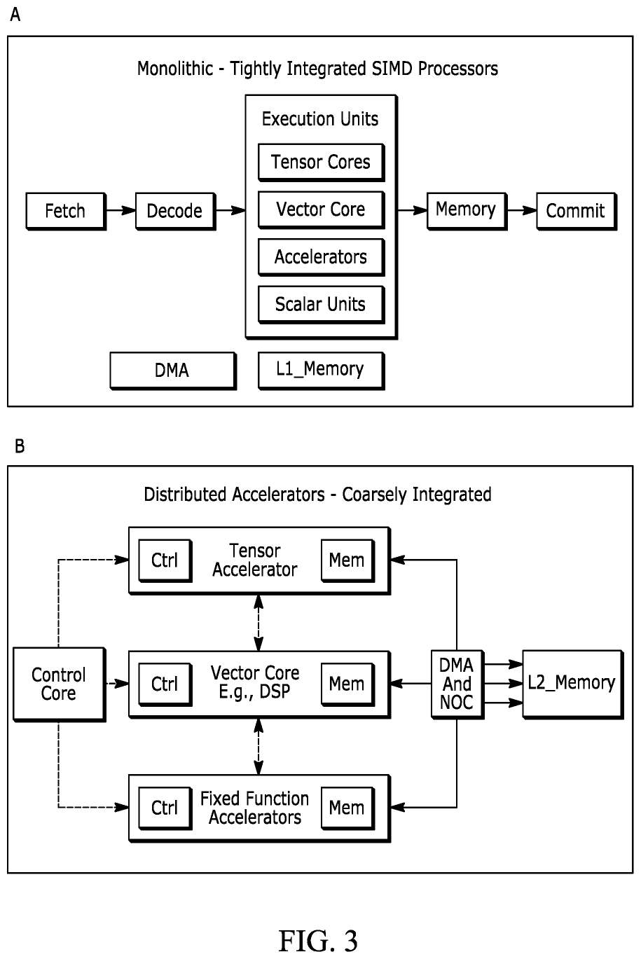

Mapping ML algorithms with high compute complexity into scalar processors is slow and inefficient. Some types of operations in CNN may be optimized by mapping to dedicated hardware processing units. For example, matrix-multiply and convolution function can be accelerated by mapping to a 2D multiply-accumulate hardware. Such implementations may benefit from additional computational resources, data-flow and hardware microarchitecture which promotes higher memory reuse, compute utilization and better area efficiency. FIG. 3 illustrates an example comparison of two ML acceleration approaches. In a first approach shown in (A) of FIG. 3, processing units (aka execution units) are tightly integrated into the processor pipeline, typically at cycle level granularity. For example, the processing units in (A) may be integrated into the execution stage of the 5-stage simple Reduced Instruction Set Computer (RISC) processor pipeline. Typically adding a new processing unit is area efficient as the new processing unit amortizes the cost of common shared resources such as core pipeline, memories etc. However, the new processing unit may add complexity as each new processing unit affects the microarchitecture of the processor itself. Also, such architecture promotes tight dataflow across processing units which are tightly coupled using memories either at register file or L1 data memory level.

The second approach shown in (B) of FIG. 3 is to build distributed processing units with its own set of control and memories and connect them using larger latency 2nd level memories and Network on chip (NOC). A common control core might be employed to synchronize across the processing units and support functionality not serviced by the dedicated processing units. Due to coarse grain integration amongst processing units, such processors might suffer from overheads communicating and synchronizing data across the units. However, such processors gain by allowing lesser micro-architecture dependencies in optimizing of each unit.

ML workloads, specifically deep-learning algorithms such as CNNs, have imposed a significant increase in compute and memory throughput requirements on modem processors. These algorithms have high parallelism, predictable memory access and gain significant hardware efficiency by optimizing for constrained operation sets, data-types and dataflows. Generic Central Processing Unit (CPU) and Digital Signal Processor (DSP) are highly programmable and optimized for various general workloads. However, the generic CPU/DSP are suboptimal in terms of compute performance, power, and area efficiency, for such modem workloads. Modern processor concepts like SIMD and VLIW significantly improved the compute throughput of such processors for many data-parallel algorithms such as signal processing, but the processors still suffer from significant inefficiencies for handling ML computations such as Neural Networks. Purposefully built ML accelerators, such as shown in (B) of FIG. 2, address these efficiency problems but introduce new challenges including limited programmability, limited support for non-ML algorithms. Particular embodiments described herein relate to systems and methods for improving the compute utilization, performance, and area/power efficiency of CPU/DSPs with SIMD and VLIW capability for key ML algorithms like CNNs, while maintaining the de-facto support for high programmability and enabling traditional workloads. Maintaining the support for high programmability and enabling traditional workloads are crucial for hybrid ML and non-ML compute pipelines particularly on an edge device which could benefit by keeping the data local in the same processing engine across a large class of algorithms, without needing to involve a dedicated fixed-function accelerator.

### Baseline Processor Architecture

In particular embodiments, a system may comprise at least a processor and an external memory coupled to the processor. The external memory may be a non-transitory memory. The processor may comprise one or more cores, one or more function units, an integrated Direct Memory Access (iDMA), and an internal memory. The processor may also comprise a Multiply-Accumulate (MAC) array, a quantizer, a first vector register array communicatively connected to the MAC array through a multiplexer (MUX), a second vector register array communicatively connected to the MAC array, and a third vector register array communicatively connected to the MAC array. The non-transitory memory may comprise instructions executable by the processor. In particular embodiments, the processor may be a very large instruction word (VLIW) processor comprising a plurality of function units. The instructions may be performed simultaneously in the plurality of function units. In particular embodiments, an instruction set architecture (ISA) of the processor may support hardware instructions associated with hardware components of the processor including the internal memory, the MAC array, the quantizer, the first vector register array, the second vector register array, and the third vector register array. In particular embodiments, the instructions are single instruction multiple data (SIMD) instructions, each of which may process a fixed-size vector data.

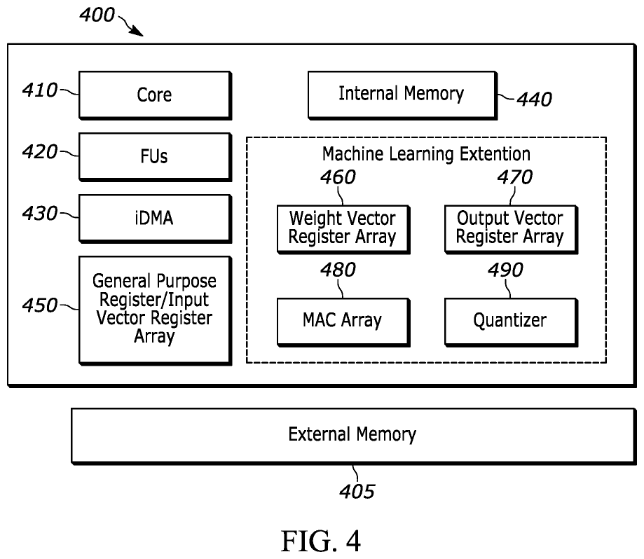

FIG. 4 illustrates an example processor architecture with additional hardware components for ML accelerations. A VLIW processor 400 may comprise one or more cores 410, a plurality of function units 420, an iDMA hardware 430 that is responsible to move data between an internal memory 440 and an external memory 405, and a number of general-purpose registers 450. The one or more cores 410 may implement basic RISC pipeline. The plurality of function units 420 may execute a variety of scalar and vector operations including arithmetic, logic, data-movements on rich data-types like floating point and integer. The number of general-purpose registers 450 may handle vector and scalar data and is a lowest level of interface to the function units 420. In particular embodiments, the general-purpose registers 450 may be used for storing input activation tensors. In particular embodiments, a dedicated input vector register array may be deployed for storing input activation tensors in the processor 400. In particular embodiments, the internal memory 440 may be a tightly coupled memory that is a software managed data storage within the processor 400. Typically, the internal memory 440 may have much higher bandwidth and lower latencies than external memories including the external memory 405. The external memory 405 may be an L2 memory outside the processor 400. The processor 400 may further comprise hardware components extended for ML acceleration purposes. Those hardware components may include a weight vector register array 460, an output vector register array 470, a Multiply-Accumulate (MAC) array 480, and a quantizer 490. Those are ISA extensions to accelerate ML operations. The ML extensions may include compute blocks such as the MAC array 480 and the quantizer 490 and specialized storage to feed the compute blocks including the weight vector register array 460 and the output vector register array 470. The ML extensions may be managed by the ISA-based core pipeline. Vector data may be fed from either the internal memory 440 or the general-purpose registers 450.

### Dataflow for Mapping ML Computations

Typical ML computations are mapped to optimal processor binaries which are either automatically generated using ML compilers or by hand-written code. Each node of the ML compute graph may be mapped to an optimized hardware component. Further, these nodes may be connected to each other using a nearest level of memory, preferably the internal memory 440. Higher-level graph optimizations may be performed by breaking down each node into smaller tiles, fusing nodes and reordering the sequence of operations to yield maximum performance for the end-end ML deployment. The system may implement each ML computation graph operation in dedicated hardware components. Operations such as convolution and matrix multiply may leverage the ML extensions, including the MAC array 480, the weight vector register array 460, and the output vector register array 470. Operations that are not supported by the ML extensions like pooling etc. will fall back to baseline function units 420 in the processor 400. The internal memory 440 and the general-purpose registers 450 may be central to pass data across nodes and to share information between the components within the processor 400. iDMA engine 430 may be employed to transfer data between the external memory 405 and the internal memory 440. The data transferred may include the ML parameters including weights and biases of a given layer and spills of intermediate activations across layer nodes which cannot be held stationary in the internal memory 440.

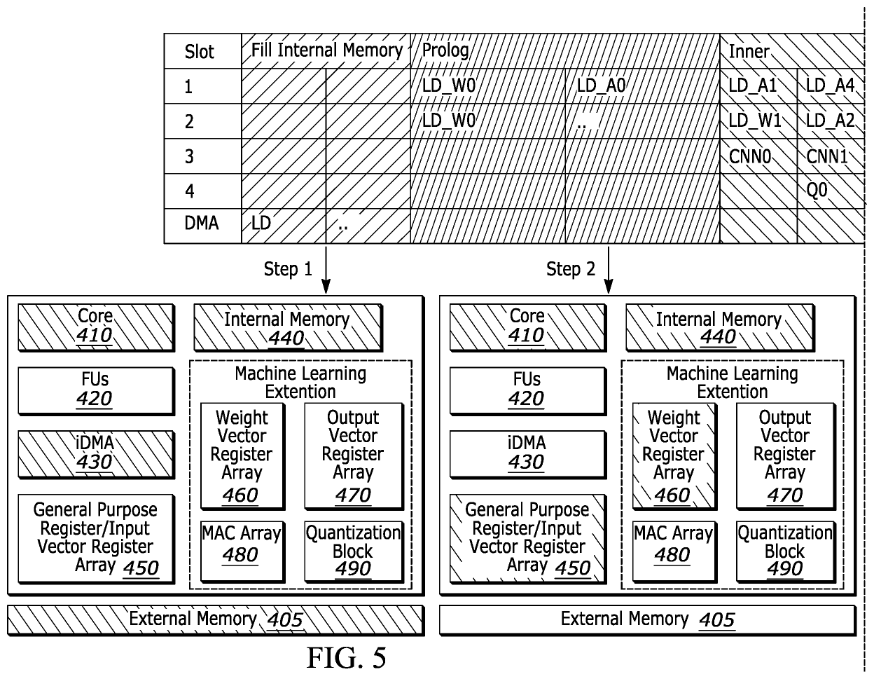

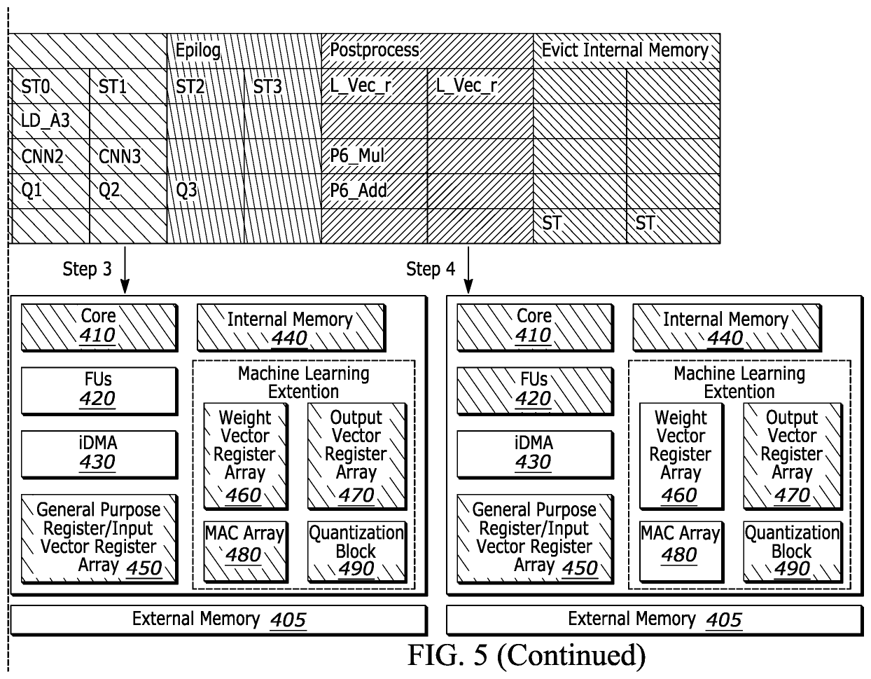

FIG. 5 illustrates an example data-flow for implementing the convolution operation. The processor in the example illustrated in FIG. 5 has 4 VLIW instruction slots. The operation is divided into a number of steps, and the hardware components used for the step are highlighted. The 5 rows represent the instruction slots, and each entry represents the ISA instruction. Each column represents the set of instructions being processed at a given cycle, with time flowing from left to right. The diagram is meant to provide a mental model for the dataflow. Details of each instruction, its functionality and implementation would be discussed later. The details are abstracted to provide brevity. For example, LD_A0 is used to load activation registers, but in implementation the instruction has other crucial fields such as the source address, the destination address/register, data-size, etc.

The iDMA 430 may be used during step 1 to load all required data to perform the convolution operation to the internal memory 440 from an external memory 405. Multiple LD instructions may be processed by the iDMA 430 during the step.

Steps 2-3 represent the software pipelined implementation of the CNN pseudo code presented in FIG. 1C. During step 2, LD_W* instruction may be used to load the filter weights to the weight vector register array 460. This step preloads the registers before they are consumed for computation in the next step. The core computation happens in step 3, in which all the resources in ML extensions are used. In the 1st cycle of this stage, a CNN* instruction is scheduled in slot3. The CNN* instruction performs 1 MAC operation based on weights and input activations loaded to the registers in the previous step and stores the output into the output vector register array 470. Simultaneously, LD_A1 and LD_W1 instructions are used to load activation and weight to be used in the next instruction. In the next cycle, Q0 instruction is scheduled in slot4 to perform fused quantization and non-linear activation of output produced by CNN0 instruction. All 4 slots are used in this cycle. ST0 instruction is scheduled in slot1 of next cycle to move the data produced by Q0 from output vector register array 470 to the internal memory 440. This process is repeated over many iterations with new data to complete the CNN. This step typically has very high utilization of the CNN instruction. Every cycle has 1 CNN scheduled and the compute utilization is considered 100% in this phase.

Remaining instructions of the CNN pseudocode, which cannot fit inside the inner loop, may be performed during the Epilog stage. Step 4, post process, is a hypothetical step which applies certain post processing to the outputs of CNN. In the example illustrated in FIG. 5, scalar multiply is performed to CNN output and is executed inside the native processor pipeline. This shows the power of the programmability of the original processor pipeline to implement new operators. Evict internal memory is an optional step where the CNN outputs in the internal memory 440 may be transferred to an external memory 405 for access by an external engine. In real situations, DMA operations may happen in parallel to compute, which is not shown in FIG. 5. The ordering of instructions in various slots to achieve best performance may be a software compiler optimization problem.

### ML Extension Architecture

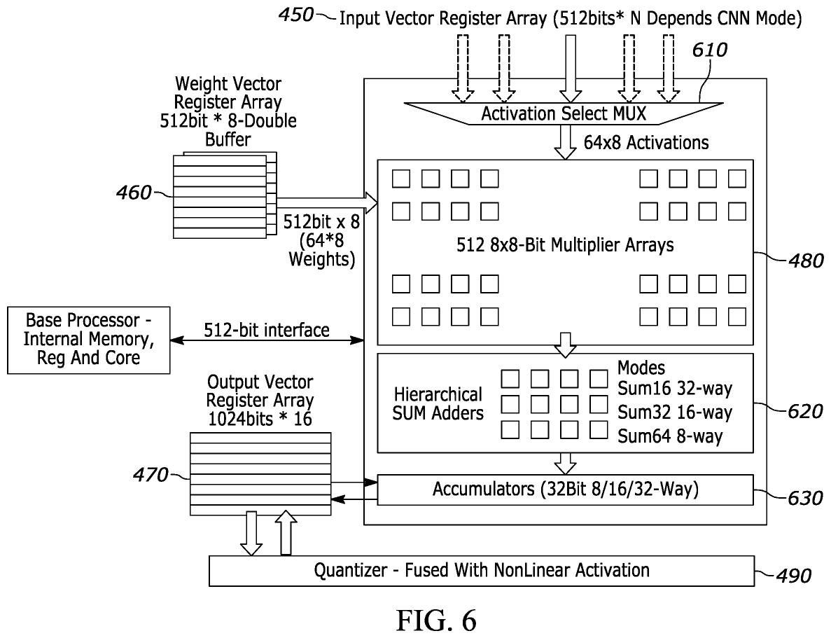

FIG. 6 illustrates an example microarchitecture of the ML extensions for convolution acceleration. The ML extensions may be connected to the baseline processor pipelines through a wide-data bus interface with tight coupling to the internal memory 440 and the general-purpose registers. The ML extensions may comprise dedicated tiled storage used in convolutions including the weight vector register array 460, the output vector register array 470, and potentially activation vector register array. In particular embodiments, the general-purpose registers 450 may be reused as the activation vector register array. The registers may be located close to the MAC array 480 and help in reusing elements across MAC operations to reduce bandwidth requirements to the internal memory 440. These registers may have tight access to the internal memory 440 and other general-purpose registers 450. The numeric precisions held in the registers may be an implementation choice which could be variable at runtime, and these are encoded in the ISA. In the example illustrated in FIG. 6, the weight vector register array 460 may comprise 8 registers each capable of storing a vector of 64 int8 values (512-bit each). The weight vector register array 460 may be double buffered to enable shadow loading of one register bank, while the other is being used for MAC computations. The output vector register array 470 may comprise 16 registers each capable of storing 32 int32 values. After the quantization operation, the output vector register array 470 may be used to hold int8 vectors. In particular embodiments, a dedicated input activation vector register array may be added to the ML extensions. In an alternative implementation, a portion of the general-purpose registers 450 may be reused to station the input activation data. Other tensors required for convolution processing such as bias and quantization parameters may be held in another portion of the general-purpose registers 450.

In particular embodiments, the registers may hold vector of variable lengths, encoded in ISA. For example, an instruction LD_W_16(source-reg, offset-src, dest-reg, offset-dest) will load 16 elements to the weight vector register array 460 from a specified offset of source-reg while LD_W_8(source-reg, offset-src, dest-reg, offset-dest) may access only 8 elements.

In particular embodiments, the MAC array 480 may consist of a plurality of MAC units, each computing a product of a weight fed from the weight vector register array 460 and an input activation fed from an input activation vector register array. The MAC array 480 may broadcast an input activation vector of size C into M (corresponding to output channel M) lanes each fed with a weight vector of size C, to compute C*M multiply operations. The input activation vector may be selected by the MUX 610 among the input activation vectors in the input activation vector register array. The C and M parameters may be configurable at runtime to enable efficient processing of various shapes of convolution operation. The configuration may be referred to as cnn_mode. In particular embodiments, cnn_mode may be configured explicitly as an encoding in the ISA instruction. In particular embodiments, cnn_mode may be configured globally in a control register. In the example illustrated in FIG. 6, the MAC array 480 may comprise 512 multipliers (MAC units) and support the following cnn_modes: {C=32, M=16}, {C=16, M=32}, and {C=64, M=8}.

In particular embodiments, the numeric could be variable precision fixed point or floating point (e.g., in4, int8, fp32, etc.), which are either configurable at runtime using ISA encoding or statically at design time. In the example illustrated in FIG. 6, int8×int8 product is performed.

In particular embodiments, the hardware components in the ML extensions may be configured to handle various shapes, process different data types, implement different activation functions and support different rounding modes. The configuration may be stored in a control register. The control register may comprise fields including activation type, group size, group/channel configuration, output rounding mode, output data type, weight data type, and input data type. The data type fields may specify which data type is used for respective data. The output rounding mode may determine one of round half up, round to nearest even, or no rounding (truncate). Since the MAC array 480 comprises 512 multipliers (MAC units), a value of the group size field and a channel size indicated in the group/channel configuration field may determine an output channel size. When the group size=1, if input channel=64, then the output channel should be 8. When the group size=1, if input channel=32, then the output channel should be 16. When the group size=1, if input channel=16, then the output channel should be 32. When group size=8 and input channel=8, then the output channel should be 8. When group size=4 and input channel=16, the output channel should be 8. When group size=4 and input channel=8, then the output channel should be 16. When group size=2 and input channel=16, then the output channel should be 16.

In particular embodiments, the MAC array 480 may have 512 MAC units that can carry out 512 8×8-bit multiplications with accumulations in a single cycle. Depending on the input/output channel dimensions of the CNN workload, the MAC array 480 can support 3 working modes when group=1:

A first mode is input channel=64 and output channel=8. In this mode, the MAC array 480 has 8 output lanes. The MAC array 480 may take 64-byte input activation data indicated by IA0-IA63 and broadcast along all 8 output lanes M0-M7. Then in each lane, a dot product will be carried out where each of the 64-byte input activation data is multiplied with 64-byte weight data of that lane. The output of the 64 multiplications may be accumulated. An output y0 of the first lane M0 may be calculated as y0=IA0*M0[0]+IA1*M0[1]+IA2*M0[2]+ . . . +IA63*M0[63]. The final sum may be stored in the output vector register array 470. An example instruction for an CNN operation in this mode may be CNN_0(v0, 0, 1), in which v0 may be a vector register containing 64-byte input activation data. The 2nd parameter is not used in this mode. The third parameter decides whether this CNN instruction overwrites the corresponding output vector register (if it's 1) or accumulates into the corresponding output vector register (if it's 0).

A second mode is input channel=32, output channel=16. In this mode, the MAC array 480 has 16 output lanes. The MAC array 480 may take a half of the elements of a 64-byte input activation vector register indicated by IA0-IA31 and broadcast along all 16 output lanes M0-M15. Then in each lane, a dot product will be carried out where each of the 32-byte input activation data is multiplied with 32-byte weight data of that lane. The output of the 32 multiplications may be accumulated. An output y0 of the first lane M0 may be calculated as y0=IA0*M0[0]+IA1*M0[1]+IA2*M0[2]+ . . . +IA31*M0[31]. The final sum may be stored in the output vector register array 470. In this mode, an input activation vector register of 64-byte is processed twice and a CNN instruction can decide which half to process based on the second parameter. Example instructions for the two CNN operations may be CNN_0(v0, 0, 1) and CNN_1(v0, 1, 1). In this mode, 2 CNN instructions are needed to process v0 register.

A third mode is input channel=16, output channel=32. In this mode, the MAC array 480 has 32 output lanes. The MAC array 480 may take a quarter of the elements of a 64-byte input activation vector register indicated by IA0-IA15 and broadcast along all 32 output lanes M0-M31. Then in each lane, a dot product will be carried out where each of the 16-byte input activation data is multiplied with 16-byte weight data of that lane. The output of the 16 multiplications may be accumulated. An output y0 of the first lane M0 may be calculated as y0=IA0*M0[0]+IA1*M0[1]+IA2*M0[2]+ . . . +IA15*M0[15]. The final sum may be stored in the output vector register array 470. In this mode, an input activation vector register of 64-byte is processed four times and a CNN instruction can decide which quarter to process based on the second parameter. Example instructions for the four CNN operations may be CNN_0(v0, 0, 1), CNN_1(v0, 1, 1), CNN_2(v0, 2, 1), and CNN_3(v0, 3, 1). In this mode, 4 CNN instructions are needed to process v0 register.

When the group size is larger than one, the 512 MAC units in the MAC array 480 may be divided into smaller groups and work accordingly depending on input/output channel sizes.

In particular embodiments, the output of the MAC units may be fed through a hierarchical adder tree 620, whose configuration may be changed at runtime, determined by the cnn_mode. The cnn_mode may specify how the different MAC units are grouped to perform the summation operation. In the example illustrated in FIG. 6, setting the cnn_mode to {M=8 or sum64} would group 64 MAC units to produce 8-way adder tree outputs, whereas setting {M=32 or sum16} would group 16 MAC units to produce 32-way outputs. The output of the adder tree 620 may be fed to a vectorized accumulator 630, which reads values from the output vector register array 470, accumulates with the outputs from the adder tree 620 and writes back the output to the output vector register array 470. Alternatively, the accumulator 630 may directly write the output of the adder tree 620 to the output vector register array 470, which may be controlled by ISA instruction encoding. The accumulator 630 in FIG. 6 may perform up to 32-way operations and be configured to perform fewer accumulations (M) based on the cnn_mode.

In particular embodiments, the numeric of the intermediate adder tree 620 and the accumulator 630 may be maintained at a higher precision than the input to the MAC unit such that accuracy is not lost. In the example illustrated in FIG. 6, int32 intermediate representation is used.

### Example Instructions Extended with ML Extensions

A set of SIMD instructions have been introduced to utilize the ML extensions. The SIMD instructions may be parallelized in a VLIW processor at runtime. In particular embodiments, the processor 400 may be operable when executing a first instruction among the instructions in the external memory 405. The first instruction, a SIMD instruction, may cause the processor 400 to load an input activation vector from the internal memory 440 to a vector register indicated by the first instruction among the first vector register array. The input activation vector may comprise C input activation values corresponding to a pixel element within an input activation tensor, where C is a number of input channels. A source location of the input activation vector in the internal memory may be indicated by the first instruction. For example LD_ATEMP0, LD_ATEMP1, . . . LD_ATEMPN may be used to load a vector register ATEMP0, ATEMP1, . . . , ATEMPN with respective activation vectors. ATEMP0, ATEMP1, . . . , ATEMPN may belong to an input activation vector register array. In particular embodiments, ATEMP0, ATEMP1, . . . , ATEMPN may be a part of the general-purpose registers 450. Basic usage may be LD_ATEMP<0-N>(mem_addr, offset), wherein the activation vector is loaded from mem_addr+offset.

In particular embodiments, the processor 400 may be further operable when executing a second instruction among the instructions in the external memory. The second instruction, a SIMD instruction, may cause the processor 400 to load a weight vector from the internal memory 440 to a vector register indicated by the second instruction among the second vector register array, wherein the second vector register array may be the weight vector register array 460. A source location of the weight vector in the internal memory 440 may be indicated by the second instruction. For example, LD_WTEMP0, LD_WTEMP1, . . . , LD_WTEMP7 can be used to load WTEMP registers, an instance of the weight vector register array 460. Basic usage may be LD_WTEMP<0-7>(mem_addr, offset), where the weight vector may be loaded from a location mem_addr+offset of the internal memory 440.

In particular embodiments, the processor 400 may be further operable to execute a third instruction among the instructions. The third instruction, a single SIMD instruction, may cause the processor 400 to feed a weight vector array from the second vector register array to the MAC array 480, wherein the second vector register array may be the weight vector register array 460. Feeding a weight vector array to the MAC array 480 may comprise providing a weight value of each element to a corresponding MAC unit of the MAC array 480. In particular embodiments, each 8-bit element in the weight vector register array 460 may be pre-associated with an MAC unit in the MAC array 480. The third instruction may also cause the processor 400 to broadcast an input activation vector to the MAC array 480. The input activation vector may be selected by the MUX 610 from the first vector register array based on the third instruction. The third instruction may further cause the processor 400 to multiply an input activation value broadcast to each MAC unit of the MAC array 480 from the input activation vector and a weight value fed to the MAC unit from the weight vector array. The third instruction may cause the processor to generate a partial output activation value for each of the M filters by accumulating outputs of MAC units corresponding to the filter. A partial output activation vector may comprise M partial output activation values. The third instruction may further cause the processor 400 to store the partial output activation vector to a vector register of the third vector register array, wherein the third vector register array may be the output vector register array 470. The storing may be an overwriting residual values of the vector register with values of the partial output activation vector or an accumulating the values of the partial output activation vector to the residual values of the vector register. For example, CNN_<0-15>(vec_reg, param0, param1) can be used for feeding a weight vector array from the weight vector register array 460 to the MAC array 480, broadcasting an input activation vector among the input activation vectors stored in a register array to the MAC array 480, performing multiplications between weights and the broadcast input activation vector by a combination of vec_reg and param0, where vec_reg indicates a vector register among a vector register array and param0 indicates which portion of the vector register to be used, generating a partial output activation value for each of the M filters by accumulating outputs of MAC units corresponding to the filter, and, store the partial output activation vector to a vector register of the output vector register array 470. param1 may indicate whether the storing is overwriting or accumulating. The vector register among the output vector register array 470 may be indicated by a value in <0-15> in the opcode. Instructions for other types of CNN operations including a single channel CNN, depth-wise CNN, and group-wise CNN are also available.

In particular embodiments, the processor 400 may be further operable to execute a fourth instruction among the instructions. The fourth instruction, a single SIMD instruction, may cause the processor 400 to modify a part of a vector register. For example, LD_OTMP 128_<0-15>(mem_addr, offset) can be used to partially modify one of OTMP registers, an instance of the output vector register array 470. The instruction loads only the first 128-bits of the 512-bit register from mem_addr+offset in the internal memory 440. The register within the register array may be indicated by <0-15> in the opcode. In particular embodiments, the processor 400 may be further operable to execute a fifth instruction among the instructions. The fifth instruction, a single SIMD instruction, may cause the processor 400 to store a part of a vector register to the internal memory 440. For example, ST_OTMP128_<0-15>(mem_addr, offset) can be used to partially store the first 128-bits of a 512-bit register indicated by <0-15> in the opcode to mem_addr+offset in the internal memory 440.

In particular embodiments, the processor 400 may be further operable when executing a sixth instruction among the instructions. The sixth instruction may cause the processor 400 to quantize n-bit numbers in a vector register among the third vector register array to m-bit numbers based on quantization parameters stored in a corresponding vector register designated for the quantization parameters. The sixth instruction may further cause the processor to perform a non-linear operation on the quantized m-bit numbers. In particular embodiments, the n-bit numbers may be 32-bit numbers. In particular embodiments, m may be 8, 16, 32, or any suitable number. For example, QUANT_<0-15>(reg1, reg0) can be used to quantize a vector register among the output vector register array 470. The vector register may be indicated by <0-15> in the opcode. The reg0 and reg1 are wide vector registers of 1536-bit (192-byte) each containing quantization data. The quantization data structure is following:

```
struct quantvar {
      short offset; //16bits 0 ... 15
      short scale; //16bits 16 ... 31
      char shift_offset; //8bits 32 ... 39
      char shift_out; //8bits 40 ... 47
};
```

When a per-layer quantization is needed, G_QUANT_0(gindex, lqindex, qvar_select) can be used, where qindex and lqindex range from 0-7 and are used to select an OTEMP register indexed from 0 through 7. qvar_select indicates whether Relu or LeakyRelu is used for a non-linear activation.

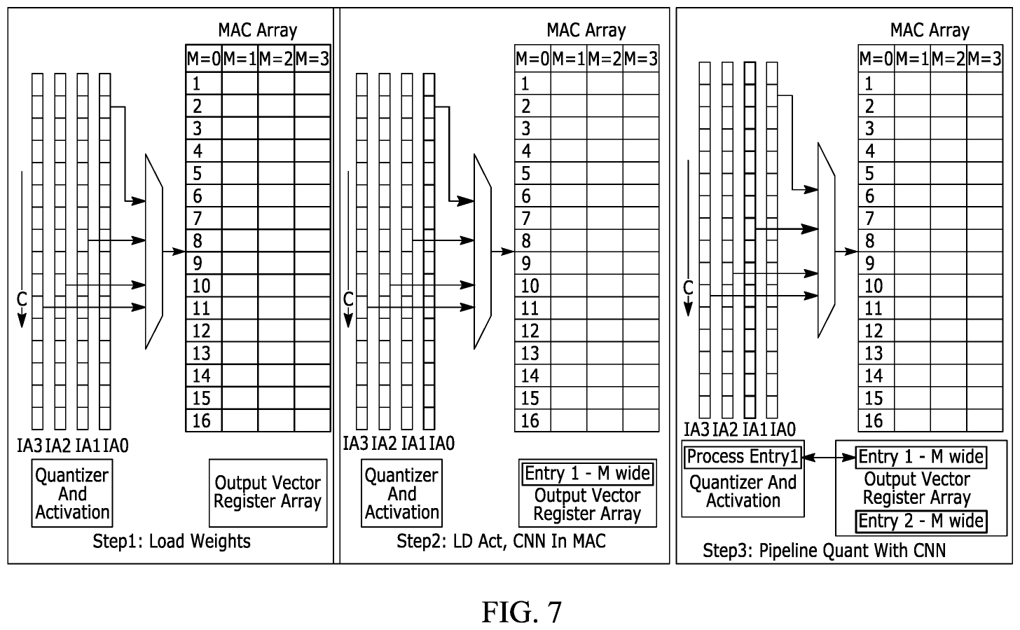

FIG. 7 illustrates an example CNN computation using the ML extensions. The example illustrated in FIG. 7 shows a hypothetical MAC array 480 of size C=16 and M=4. The weight vector register array 460 is not explicitly shown in FIG. 7. The height and width of the filters are assumed to be RXS=1×1 (equivalent to a matrix multiply).

First, the weight vector register array 460 may be loaded from the internal memory 440. The weight tensors can be arranged in a hardware efficient layout like MXC a-priori and is loaded into the weight vector register array of size C*M. Loading weight vectors may consume multiple cycles/steps based on the bandwidth available to the internal memory 440. Second, activation registers may be loaded from the internal memory 440. The activation registers may be a dedicated input activation vector register array, or a part of the general-purpose registers 450. Each activation vector is in C-dimension. Loading activation vectors may take multiple cycles. The reg vector is loaded in the IA0 activation register in the example illustrated in FIG. 7. Next, a MAC operation may be performed. The IA0 vector of size C is broadcast across the M weight vectors to produce an output of vector length M. Each output is a dot-product of the weights and a corresponding element of IA0. The M outputs are accumulated into a vector register in the output vector register array 470. The MAC operations may be repeated on different activation vectors. In parallel, processor 400 may post-process the outputs in the output vector register array 470 using the fused quantizer and activation unit. Store the output back into the internal memory 440, with potentially holding the quantized data back in the output vector register for buffering. In particular embodiments, the basic flow may be customized for each shape of CNN or matrix multiply. For example, a 2×2 (RXS) convolution can be implemented by accumulating into the same accumulator over 4 iterations. The full ISA control may enable the dataflow to be a software decision which can be optimized based on the shape of CNN/matmul hardware component.

Operation sequence for CNN Acceleration

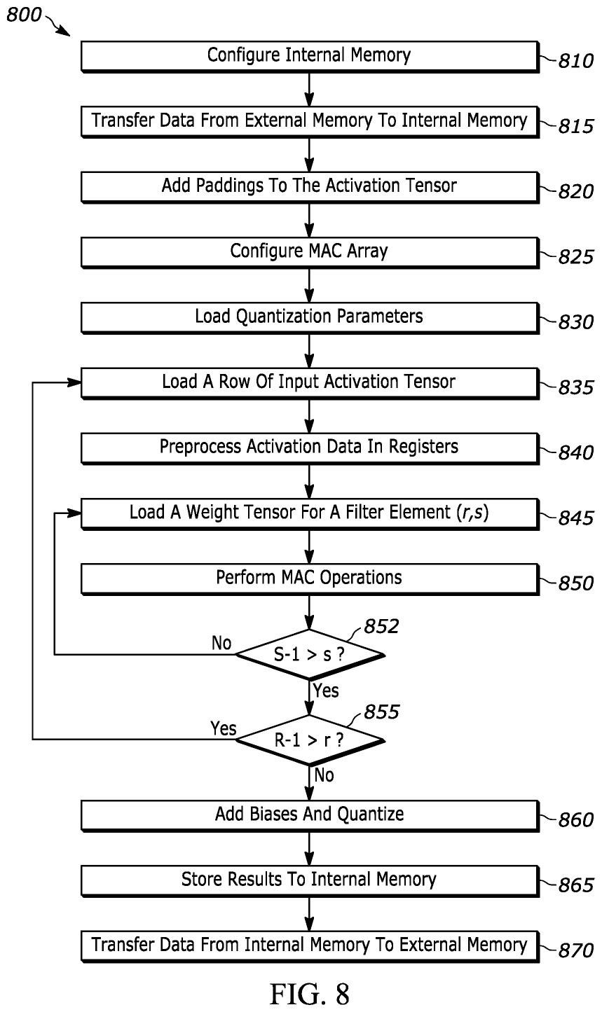

FIG. 8 illustrates an example operation sequence to compute convolution between an input activation tensor and M filters. At step 810, the processor 400 may configure the internal memory 440. At step 815, the processor 400 may transfer data required for the convolution from an external memory 405 into the internal memory 440. At step 820, the processor 400 may add paddings required for the convolution to the input activation tensor in the internal memory 440. At step 825, the processor 400 may configure a shape of the MAC array 480 to optimize the convolution. At step 830, the processor 400 may load quantization parameters 830 to registers designated for the quantization parameters. At step 835, the processor 400 may load a row of the input activation tensor from the internal memory 440 into an input activation vector register array. At step 840, the processor 400 may preprocess the loaded row of the input activation tensor in the input activation vector register array to optimize the performance of the convolution. At step 845, the processor 400 may load a weight tensor corresponding to a filter element (r, s) from the internal memory 440 to the weight vector register array 460. The loaded weight tensor may be a C-by-M matrix, where C is a number of input channels and M is a number of filters used for the convolution operations. At step 850, the processor 400 may perform MAC operations between the loaded filter element and a corresponding row of the input activation tensor. At step 852, the processor may determine whether all the filter elements in the current row r have been processed with the corresponding row of the input activation tensor. If no, the sequence moves back to step 845 where the processor 400 loads a weight tensor for a next filter element. If yes, the sequence proceeds to step 855, where the processor 400 may determine whether convolutions on the last row of the filters have been performed. If no, the sequence moves back to step 835 where the processor 400 loads a row of the input activation tensor. If yes, the sequence proceeds to step 860, where the processor 400 may add biases to the output in the output vector register array 470 and quantize the output. At step 865, the processor 400 may store the results from the output vector register array 470 to the internal memory 440. At step 870, the processor may transfer data from the internal memory 440 to the external memory 405.

In particular embodiments, the processor 400, at step 810, may configure one or more banks of the internal memory 440 with configuration information including one or more bank sizes and one or more alignment sizes. The internal memory 440 may be a tightly coupled memory that might be software managed. The system may let the software managed memory filled and evicted to higher levels of memory using DMA over using L1 cache, which is typical in processor workloads. The approach may help to achieve better performance for ML extension hardware components, for which the memory sequence can be known a priori at compile time. Multiple banks for the internal memory 440 may be present in hardware to allow simultaneous access to these banks, without having bank conflicts. Bank configuration for the internal memory 440 may be a first step before executing the CNN workloads and the desired internal memory sizes for bank0 and bank1 are specified. An example configuration operation may be MEM_init(bank0_size, alignment_size, bank1_size, alignment_size). The MEM_init( ) function may allocate bank0_size and bank1_size for bank0 and bank1 and the initial addresses of bank0 and bank1 may be aligned by alignment_size. The processor may allocate buffers within the internal memory for input activation tensor, output activation tensor, weights, or biases. An example buffer configuration may be done by MEM_buffer_alloc(buffer, bank_index, allocation_size, alignment_size).

In particular embodiments, the processor 400, at step 815, may transfer weights for M filters, an input activation tensor, biases, and information associated with configurations from an external memory 405 to the internal memory 440. Example data transfer may be done by dma_smem2MEM(smem_addr, buffer_addr, transfer_size). Usually, iDMA may be used for the data transfer. However, load/store instructions may be used for the transfer as well.

In particular embodiments, the processor 400 may insert paddings to the input activation tensor in the internal memory based on first configuration parameters at step 820. The first configuration parameters may be determined based at least on an activation tensor width, an activation tensor height, an output activation tensor width, an output activation tensor height, and a stride. The paddings may increase width or height of the input activation tensor. For convolutions with filter size larger than one, the input activation data may need to be converted from a continuous 1D layout to 2D layout in order to accommodate the paddings along width and height dimensions. To insert the paddings to the activation tensor, the processor 400 may allocate a second memory space for an activation matrix corresponding to each channel of the activation tensor along with a configured-number of paddings in the internal memory 440. The processor 400 may initialize the configured-number of paddings in the second memory space. Then, the processor may copy data for each row of the activation matrix from a first memory space to a respective memory chunk in the second memory space. In the first memory space, the activation matrix may be stored in a sequence.

The ML extension hardware components including the MAC array 480 may be reconfigurable to calculate various types and dimensions of CNN workloads efficiently. For example, the MAC array 480 may calculate 1×1 CNNs, 3×3 CNNs, depth-wise and group-wise CNNs. In particular embodiments, at step 825, a shape of the MAC array may be dynamically configured at runtime to a required shape for convolution operations based on hardware configuration parameters stored in a register array designated for the hardware configuration parameters. The hardware configuration parameters may be determined based at least on C, a number of input channel, and M, a number of filters used for the convolution operations. In particular embodiments, the shape of the MAC array may be configured to C-by-M. An output activation tensor generated as a result of the convolution operations may have M channels. In particular embodiments, possible combinations of C and M may include (64, 8), (32, 16), (16, 32), or any suitable combination.

In particular embodiments, the processor 400 may, at step 830, load the quantization parameters of the CNN workloads into wide-vector registers from the internal memory 440 if per-channel quantization configurations are needed. The loading to wide-vector registers may be a 2-step operation: first, the quantization parameters may be loaded from the internal memory 440 into vector registers. Then the quantization parameters may be loaded into wide-vector registers from vector registers. If a layer quantization is used, a single state register may be used for quantization parameters.

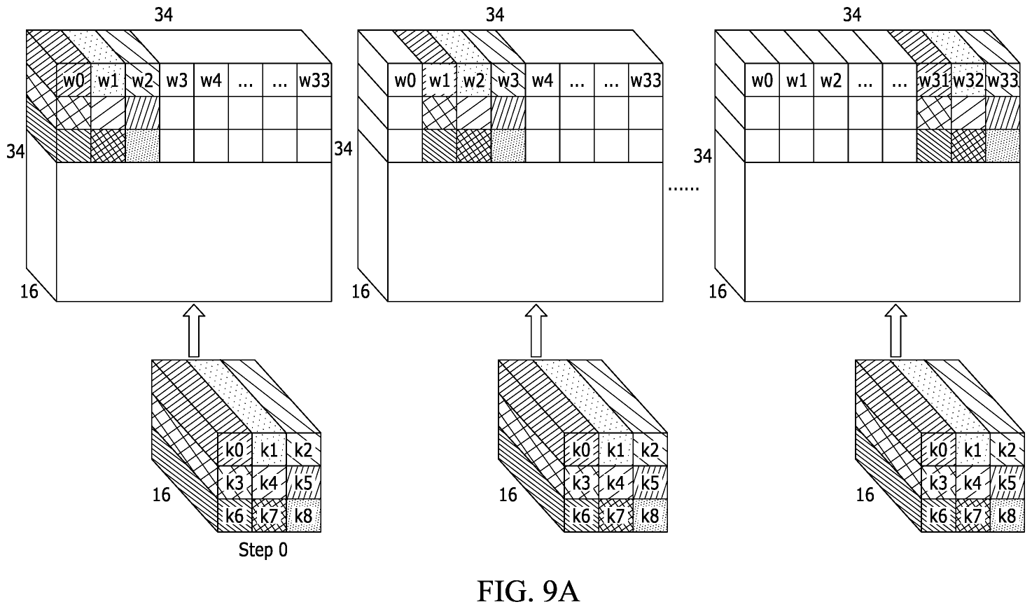

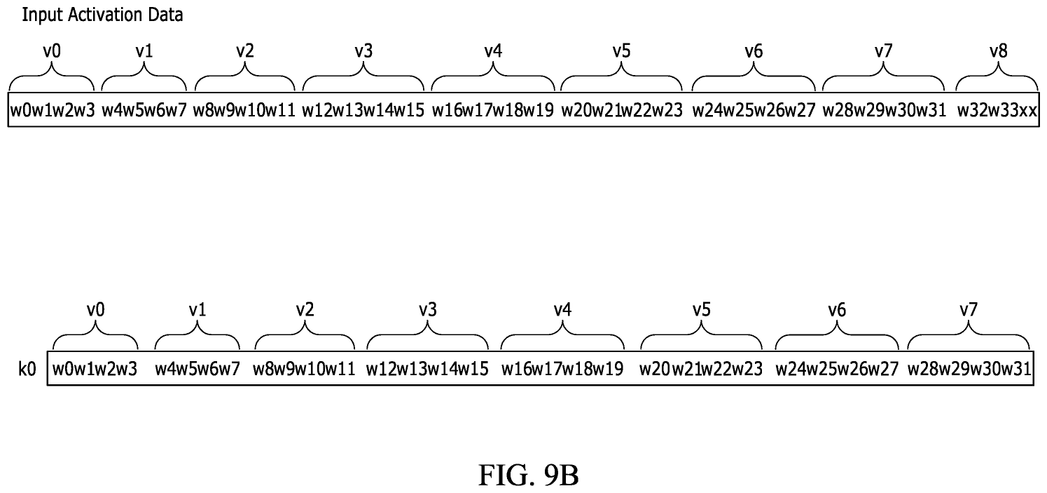

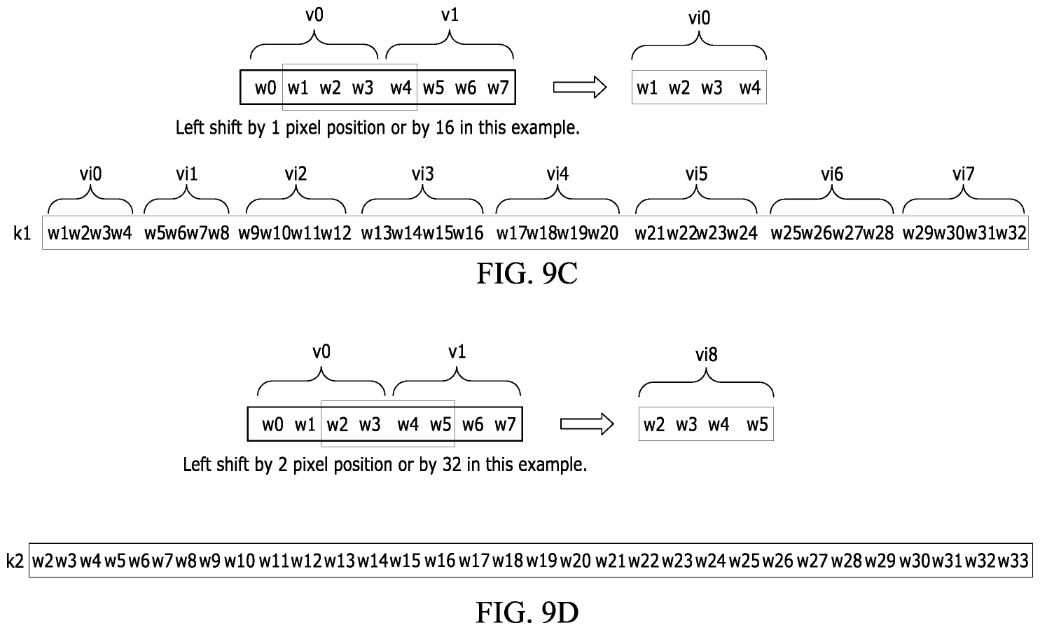

FIG. 9A illustrates an example illustration of a 3×3 convolution between a 34×34×16 input activation tensor and a 3×3×16 filter. Assuming stride=1, a filter element k0 at coordinates (0, 0) of the filter needs to be multiplied to each of the activation element from w0, w1, . . . , w31 of row 0 of the input activation tensor as a first part of calculating pixel elements in the first row of an output activation tensor for a channel, indicated by {o0, o1, . . . , o31}. Likewise, a filter element k1 at coordinates (0, 1) of the filter needs to be multiplied to each of the activation elements from w1, w2, . . . , w32 of row 0 of the input activation tensor as a second part of calculating pixel elements in row 0 of the output activation tensor for the channel. A filter element k2 at coordinates (0, 1) of the filter needs to be multiplied to each of the activation elements from w2, w3, . . . , w33 of row 0 of the input activation tensor as a third part of calculating pixel elements in row 0 of the output activation tensor for the channel. Since a single filter element needs to be multiplied with several activation elements in a row for the calculation of a row of output activation tensor, the calculations may be optimized by holding the filter elements stationary for multiplication across different activation elements.

In particular embodiments, the processor 400 may, at step 835, load a row of the input activation tensor involved in the convolution to an input activation vector register array. When performing RxS convolution operations between the input activation tensor and M filters, the processor 400 may calculate each row e of an output activation tensor of the convolution operations by performing the convolution operations on corresponding R rows {h₀^{e}, . . . , h_{R-1}^{e}} of the input activation tensor with the M filters, where R is a filter height. The processor may calculate the output activation tensor row-by-row. A pixel element on row e of the output activation tensor may comprise M channels. To calculate row e of the output activation tensor, the processor may calculate multiplications for each row r among R rows of the filters. For calculating multiplications of weight elements in row r of the filters to generate row e of the output activation tensor, the processor may first determine that row hᵣ^{e} of the input activation tensor that corresponds to row r of the filters for calculating row e of the output activation tensor by hᵣ^{e}=e×U_{y}+r, where U_{y} is a vertical stride for the convolution operations, and where e, r, and hᵣ^{e} are zero-based indices. Once the row hᵣ^{e} of the input activation tensor is determined, the processor 400 may load the row hᵣ^{e} into the input activation vector register array. In particular embodiments, the input activation vector register array may be a vector register array dedicated to input activation data. In particular embodiments, the input activation vector register array may be the general-purpose registers 450.

In particular embodiments, the processor 400 may, at step 840, preprocess the loaded row of the input activation tensor in the input activation vector register array to optimize the performance of the convolution. For each column s, where s begins at zero, of the filters, the processor may optimize convolution operations between a filter element at coordinates (r, s) from each of the M filters and valid pixel elements in row hᵣ^{e} of the input activation tensor. For the optimized convolution operations, the processor may load P pixel elements starting from pixel element s of row hᵣ^{e} of the input activation tensor to the first vector register array, where P=W-S+1, where W is an input tensor width, and S is a filter width. Each pixel element may comprise an input activation vector of size C. The processor may execute the first instruction a number of times with different parameters to load P pixel elements starting from pixel element s of row hᵣ^{e} of the input activation tensor to the first vector register array. FIG. 9B illustrates an example row of an input activation tensor loaded to first vector registers to be multiplied with k0, a filter element at column 0. In the example illustrated in FIG. 9B, each of the vector registers {v0, v1, . . . , v7}contains four 16 channel input activation vectors. v0 contains {w0, w1, w2, w3}, v1 contains {w4, w5, w6, w7}, . . . , and v7 contains {w28, w29, w30, w31}. By organizing the vector register array in this manner, a filter element k0, at coordinates (0, 0), of the filters can be multiplied with all the valid pixel elements in row hᵣ^{e} of the input activation tensor without replacing weight vectors in the weight vector register array 460. FIG. 9C illustrates an example row of an input activation tensor loaded to second vector registers to be multiplied with k1, a filter element at column 1. In the example illustrated in FIG. 9C, each of the vector registers {vi0, vi1, . . . , vi7} contains four 16 channel input activation vectors starting from w1. vi0 contains {w1, w2, w3, w4}, vi1 contains {w5, w6, w7, w8}, . . . , and vi7 contains {w29, w30, w31, w32}. By organizing the vector register array in this manner, a filter element k1, at coordinates (0, 1), of the filters can be multiplied with all the valid pixel elements in row hᵣ^{e} of the input activation tensor without replacing weight vectors in the weight vector register array 460. FIG. 9D illustrates an example row of an input activation tensor loaded to third vector registers to be multiplied with k2, a filter element at column 2. In the example illustrated in FIG. 9D, each of the vector registers {vi8, vi9, . . . , vi15} contains four 16 channel input activation vectors starting from w2. vi8 contains {w2, w3, w4, w5}, vi9 contains {w6, w7, w8, w9}, . . . , and vi15 contains {w30, w31, w32, w33}. By organizing the vector register array in this manner, a filter element k2, at coordinates (0, 1), of the filters can be multiplied with all the valid pixel elements in row hᵣ^{e} of the input activation tensor without replacing weight vectors in the weight vector register array 460.

In particular embodiments, for the optimized convolution operations between filter elements at coordinates (r, s) from the M filters and valid pixel elements in row hᵣ^{e} of the input activation tensor, at step 845, the processor 400 may load a filter element at coordinates (r, s) from each of the M filters to the second vector register array. The processor 400 may load a filter element at coordinates (r, s) of the M filters from the internal memory 440 to the weight vector register array 460. A filter element of each filter may comprise a weight vector of size C. In particular embodiments, the processor 400 may be further operable when executing the second instruction. The second instruction may cause the processor 400 to load a weight vector from the internal memory 440 to a vector register indicated by the second instruction among the second vector register array. A source location of the weight vector in the internal memory 440 may be indicated by the second instruction. Each weight vector in the weight vector array may comprise C weight values. The weight vector array may comprise a filter element at a position of M filters. The processor may execute the second instruction a number of times with various parameters to load filter elements at coordinates (r, s) of the M filters. For example, continuing with a prior example illustrated in FIG. 9A, the processor 400 may load filter element k0 from each of M filters to the weight vector register array 460.

In particular embodiments, the processor may calculate a partial output activation vector for each valid pixel element k among the P pixel elements in the first vector register array by executing the third instruction, where the valid pixel element k at an iteration l is determined as k=l*Uₓ, where Uₓ is a horizontal stride for the convolution operations, wherein P=W−S+1, and where k and l are zero-based indices. For example, continuing with a prior example illustrated in FIG. 9B, if the horizontal stride is assumed to be 1, the pixel element at iteration 0 is w0, the pixel element at iteration 1 is w1, . . . , and the pixel element at iteration 31 is w31. For another example, continuing with a prior example illustrated in FIG. 9C, if the horizontal stride is assumed to be 1, the pixel element at iteration 0 is w1, the pixel element at iteration 1 is w2, . . . , and the pixel element at iteration 31 is w32.

In particular embodiments, for calculating a partial output activation vector, the processor may (a) perform M*C element-wise multiplications between the pixel element k and the filter element at coordinates (r, s) of M filters; (b) generate a partial output activation vector having M output channels by summing results of multiplications belonging to a respective filter; and (c) accumulate the partial output activation vector to a corresponding vector register among the third vector register array. To perform M*C element-wise multiplications between the pixel element k and the filter element at coordinates (r, s) of M filters, the processor may feed M weight vectors in the second vector register array to a corresponding column of the MAC array. Each of the M weight vectors may be a filter element at coordinates (r, s) from respective filter among the M filters. Then, the processor may broadcast an input activation vector in the first vector register array to columns of the MAC matrix. The input activation vector may correspond to the pixel element k among the W−S+1 pixel elements in the first vector register array. The MUX may select a vector register containing the pixel element k among the first vector register array containing the W−S+1 pixel elements. Finally, the processor may perform a multiplication at each MAC unit in the MAC matrix between a respective activation value of the pixel element k corresponding to a channel and a respective weight value of the filter element at coordinates (r, s) corresponding to the channel from one of the M filters. For example, continuing with a prior example illustrated in FIGS. 9A-9D, the processor 400 may initialize the output vector register array 470 with zeros. For brevity purposes, we assume that a size of the output vector register array 470 is large enough. The processor 400 may load the pixel element k0 of M filters to the weight vector register array 460. And, the processor may load the row 0 of the input activation tensor as shown in FIG. 9B. The processor 400 may store a partial output activation vector by performing M*C element-wise multiplications and column-wise accumulating the output of element-wise multiplications between k0 and w0 to an output vector register o0 in the output vector register array 470. The processor 400 may store a partial output activation vector of k0 and w1 to an output vector register o1. The processor 400 may keep processing low 0 of the input activation tensor through w31. A partial output activation vector of k0 and w31 may be stored to an output vector register o31. The processor 400 may move to the filter element k1 by loading k1 into the weight vector register array 460. The processor 400 may accumulate a partial output activation vector of k1 and w1, a first element illustrated in FIG. 9C, to the vector stored in the output activation vector o0. The processor 400 may accumulate a partial output activation vector of k1 and w2, a second element illustrated in FIG. 9C, to the vector stored in the output activation vector o1. The processor 400 may keep processing low 0 of the input activation tensor from w1 through w32 with the filter element k1. A partial output activation vector of k1 and w32 may be accumulated to the output vector register o31. The processor 400 may move to the filter element k2 by loading k2 into the weight vector register array 460. The processor 400 may accumulate a partial output activation vector of k2 and w2, a first element illustrated in FIG. 9D, to the vector stored in the output activation vector o0. The processor 400 may accumulate a partial output activation vector of k2 and w3, a second element illustrated in FIG. 9D, to the vector stored in the output activation vector o1. The processor 400 may keep processing low 0 of the input activation tensor from w2 through w33 with the filter element k2. A partial output activation vector of k2 and w33 may be accumulated to the output vector register o31. The processor 400 may move to row 1 of the filters. The processor 400 may load filter element k3 into the weight vector register array 460. The processor 400 may load row 1 of the input activation tensor to the activation registers. The row 1 of the input activation tensor may be reorganized in manners illustrated in FIGS. 9B, 9C, and 9D. The partial output activation vectors of k3 and pixel elements in row 1 of the input activation tensor may be accumulated to output vector register array {o0, o1, . . . , o31}. When the processor 400 finishes all the calculations associated with k0 through k8, the output vector register array {o0, o1, . . . , o31} may contain data corresponding to row 0 of the output activation tensor. The processor 400 may quantize the values of the output vector register array and perform non-linear activations on the quantized values to get row 0 of the output activation tensor.

In particular embodiments, the processor 400 may perform quantization operations on the third vector register array using the quantizer 490 based on quantization parameters by executing the fourth instruction. A quantization operation comprises a non-linear activation operation. Parameters associated with the non-linear activation operation may be in the quantization parameters stored in the corresponding vector register. The quantization operation may further comprise adding a bias. Parameters associated with the bias may be stored in a corresponding vector register. The third vector register array may comprise 32-bit elements. In particular embodiments, the processor may store row e of the output activation tensor in the third vector register array to the internal memory. For example, continuing with a prior example illustrated in FIGS. 9A-9D, the output vector register array {o0, o1, . . . , o31} may be quantized on the quantizer 490. A pre-configured non-linear activation operation may be performed on values in the output vector register array {o0, o1, . . . , o31}. Pre-configured biases may be added the values of the output vector register array {o0, o1, . . . , o31}. The values of the output vector register array may be stored to the internal memory 440.

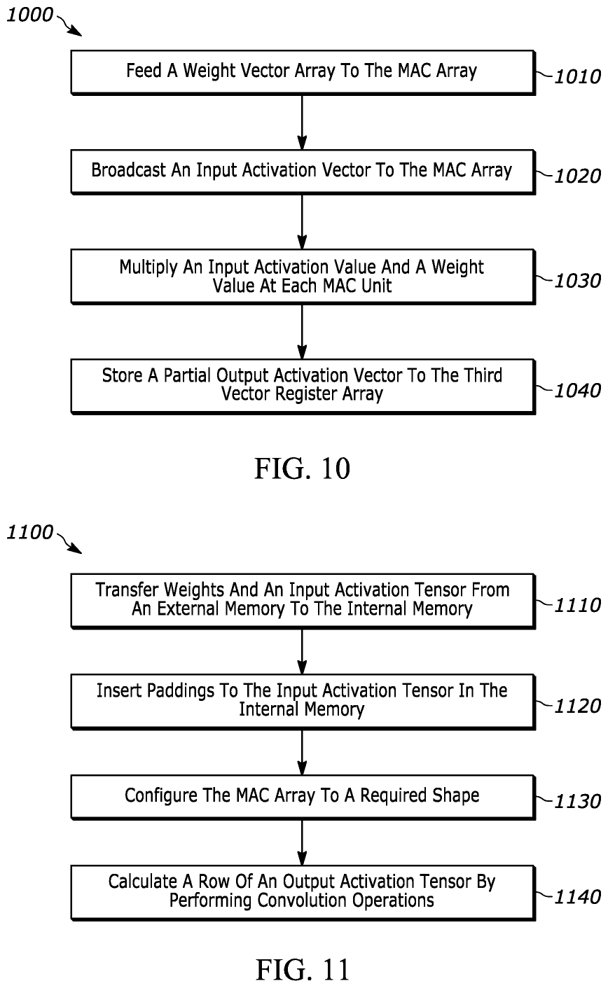

FIG. 10 illustrates an example method 1000 for performing a series of operations associated with convolution by executing a single instruction. The method may begin at step 1010, where the processor may feed a weight vector array from a second vector register array to an MAC array. At step 1020, the processor may broadcast an input activation vector to the MAC array. The input activation vector is selected by a MUX from a first vector register array based on the single instruction. At step 1030, the processor may multiply an input activation value broadcast to the MAC unit from the input activation vector and a weight value fed to the MAC unit from the weight vector array at each MAC unit in the MAC array. At step 1040, the processor may store a partial output activation vector to the third vector register array, where the partial output activation vector is the output of the MAC array. Particular embodiments may repeat one or more steps of the method of FIG. 10, where appropriate. Although this disclosure describes and illustrates particular steps of the method of FIG. 10 as occurring in a particular order, this disclosure contemplates any suitable steps of the method of FIG. 10 occurring in any suitable order. Moreover, although this disclosure describes and illustrates an example method for performing a series of operations associated with convolution by executing a single instruction including the particular steps of the method of FIG. 10, this disclosure contemplates any suitable method for performing a series of operations associated with convolution by executing a single instruction including any suitable steps, which may include all, some, or none of the steps of the method of FIG. 10, where appropriate. Furthermore, although this disclosure describes and illustrates particular components, devices, or systems carrying out particular steps of the method of FIG. 10, this disclosure contemplates any suitable combination of any suitable components, devices, or systems carrying out any suitable steps of the method of FIG. 10.

FIG. 11 illustrates an example method 1100 for generating an output activation tensor by performing convolution operations on an input activation tensor with M filter. The method may begin at step 1110, where the processor may transfer weights for M filters and an input activation tensor from an external memory to the internal memory. At step 1120, the processor may insert paddings to the input activation tensor in the internal memory based on first configuration parameters. The paddings may increase width or height of the input activation tensor. At step 1130, the processor may configure a MAC array to a required shape based on second configuration parameters for convolution operations between the input activation tensor and the M filters. At step 1140, the processor may calculate a row of an output activation tensor by performing the convolution operations on corresponding R rows of the input activation tensor with the M filters, for each of E rows of the output activation tensor of the convolution operations, where R is a filter height. Particular embodiments may repeat one or more steps of the method of FIG. 11, where appropriate. Although this disclosure describes and illustrates particular steps of the method of FIG. 11 as occurring in a particular order, this disclosure contemplates any suitable steps of the method of FIG. 11 occurring in any suitable order. Moreover, although this disclosure describes and illustrates an example method for generating an output activation tensor by performing convolution operations on an input activation tensor with M filter including the particular steps of the method of FIG. 11, this disclosure contemplates any suitable method for generating an output activation tensor by performing convolution operations on an input activation tensor with M filter including any suitable steps, which may include all, some, or none of the steps of the method of FIG. 11, where appropriate. Furthermore, although this disclosure describes and illustrates particular components, devices, or systems carrying out particular steps of the method of FIG. 11, this disclosure contemplates any suitable combination of any suitable components, devices, or systems carrying out any suitable steps of the method of FIG. 11.

### Accelerating Depth-Wise Convolutions

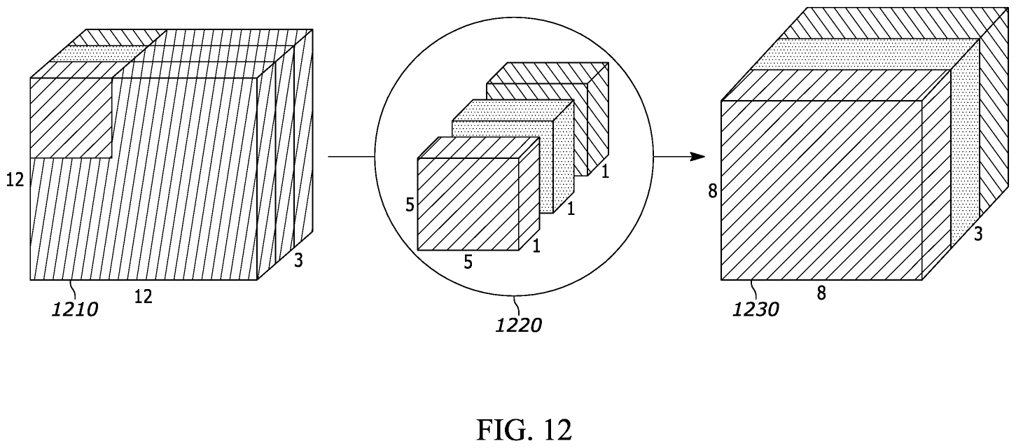

Standard convolution may have too many parameters, which may crease a chance of over-fitting. To avoid such scenarios, different approaches including depth-wise (DW) convolution have been considered. FIG. 12 illustrates example depth-wise convolutions. In the example illustrated in FIG. 12, dimensions of an inputivation tensor 1210 are 12×12 (HxW) with three channels. DW convolutions on the activation tensor 1210 with a filter 1220 of 5×5 (RxS) with M=3 may result in a 8×8 output activation tensor 1230 with 3 channels. Depth-wise convolutions, also known as DW-conv, may be constrained forms of convolutions. In DW-conv the M and C dimensions are merged, to significantly decrease the compute requirements of convolution. In FIG. 12, each input channel is convolved with its corresponding weight plane to produce an output channel. Each output channel is influenced only by its corresponding input channel. So using the same dataflow similar to the baseline design illustrated in FIG. 4, which does a MAC across multiple input channels, may lead to poor resource utilization (only 1 MAC in each lane is used). As each input channel influences only one output channel, unlike traditional convolution where each input channel influences M output channels, broadcasting an input activation vector corresponding to a pixel element to all lanes would not work. A new MAC array optimization is proposed herein to achieve good compute utilization, while also handling tensor data-layout which are conducive for operations which exist before and after the DW-conv in the ML computation graph. The proposal not only enhances the architecture presented in FIG. 4, but also is applicable to other MAC array-based architecture. In particular embodiments, the control at runtime could be either using a dedicated ISA instruction or by setting special registers.

To enable vectorization in DW-conv, accumulation may be performed in the spatial dimension instead of channel dimension. An example equation for a RxS(3×3) convolution, when M output channels assumed, may be: Out[0][0][M]=IA[0] [0][M]*W[M][0][0]+IA[0][1][M]*W[M][0][1]+IA[0][2][M]*W[M][0]1[2]+IA[1][0][M]*W[M][1][0]+IA[1][1][M]*W[M][1][1]+IA[1][2][M]*W[M][1][2]+IA[2][0][M]*W[M][2][0]+IA[2][1][M]*W[M][2][1]+IA[2][2][M]*W[M][2][2]. For a 3×3 convolution, 9 MAC units may be used in each lane. Also, maintaining same layout for an input activation tensor and an output activation tensor for DW_conv as regular convolutions may be preferable to avoid cycles spent in transforming the layout across regular convolutions and DW convolutions.

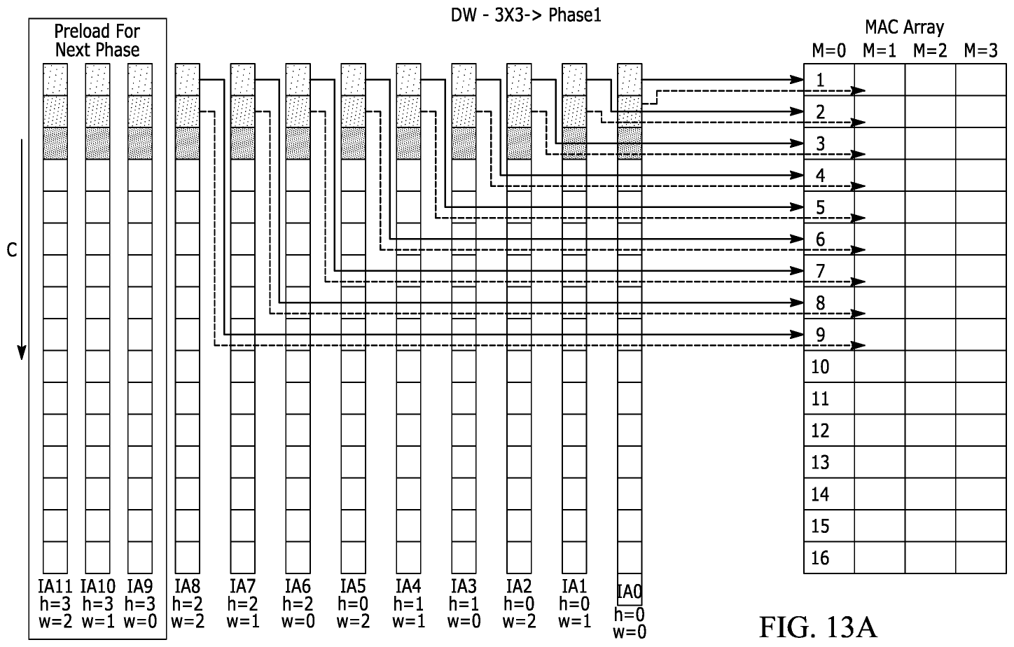

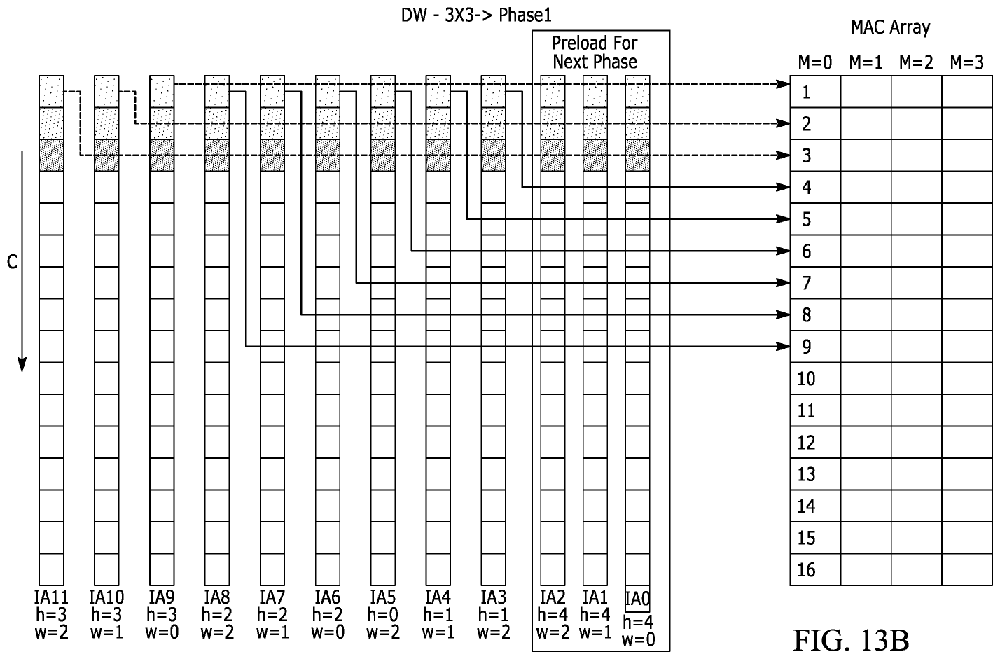

The MAC array architecture in FIG. 6 may be modified to unicast each input activation to each output lane separately. The modification may allow the MAC array to be fed with independent input activation across each lane. FIGS. 13A-13B illustrate example routing of data for 2 lanes of the MAC array for depth-wise convolutions during phase 1 and phase2. A number of lanes in the MAC array may be M, a number of layers of the filter, which eventually becomes a number of output channels. Each element in an input activation (IA) vector may represent a channel. Each IA Vector Register could be up to C elements wide, a value of 64 will be used in this discussion. Each register holds a different pixel element of the input activation tensor. Thus, IA0 may contain pixel element from coordinates (0, 0) in the input activation tensor. The example illustrated in FIG. 13 shows an MAC array with C=16 optimized to handle 3×3 (RxS) DW-Conv. The MAC array may be custom designed for other sizes as well. For example, an MAC array designed only for 3×3 DW-conv may have only 9 MAC cells per M-lane.

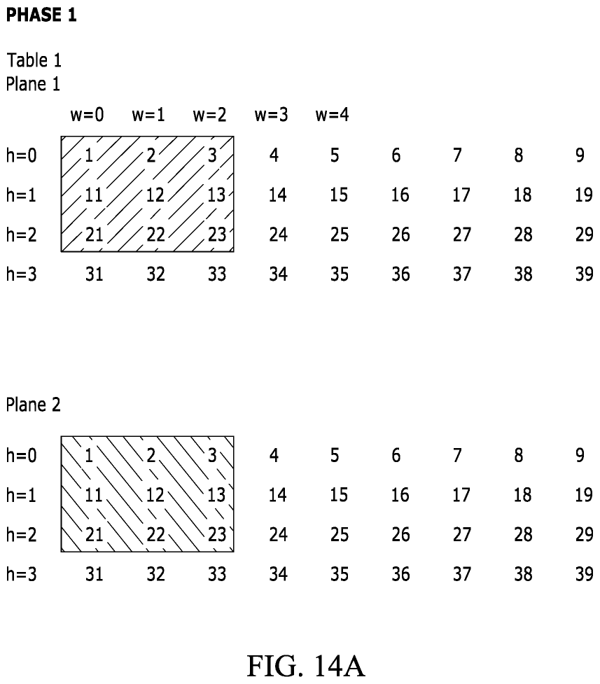

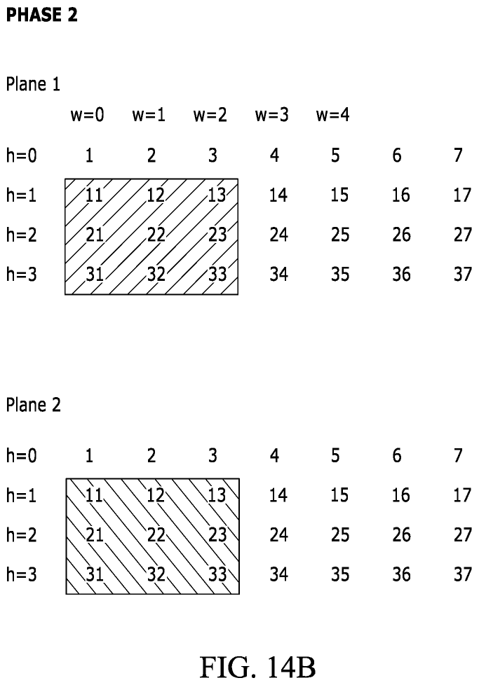

FIGS. 14A-14B illustrates example DW convolution operations for a RXS=3×3 with stride=1 during phase 1 and phase 2. The numbers may represent the input activations; the highlighted region is the filter overlap being processed in the illustrated phase. The values of weights are not shown for brevity. In phase1, the input channels are convolved with input activations as shown in FIG. 14A. FIG. 13A shows the MAC array structure and data flow for first two input channels during phase 1. That can be extended to all M/C planes. While the computation of IA0 to IA7 happens in phase 1, IA9-IA11 are being loaded for being used in the next phase. Since 9 values are vectorized as discussed earlier, 9 out of the 16 MAC cells in the original array are being used in the array with C=16, and the rest of the 7 MAC engines are unused by hardware. Dedicated array for 3×3 convolution with C=9 may help achieve 100% utilization.

In Phase 2 the filter is moved along the height dimension by a stride of 1, which is shown in FIG. 14B. FIG. 13B shows the MAC array dataflow in phase2. IA3-IA11 are used for computation while IA0-IA2 are used to preload input activation for the next phase. The entire DW-convolution can be achieved by processing along ‘n’ phases.

Accelerating Convolutions with a Single Input Channel

Mapping convolutions with a single channel input activation tensor in a MAC array presented in FIG. 6 may pose a number of problems. First, the compute utilization per lane of the MAC array is just 1/C. Also, the input activations may need to be 0 padded. In such a scenario, all lanes except the 1st C would be 0s. This may require larger storage, larger bandwidth to copy these padded data in the memory hierarchy, and more cycles for performing these transformations itself. Such convolutions may benefit from vectorizing the math along the spatial dimension.

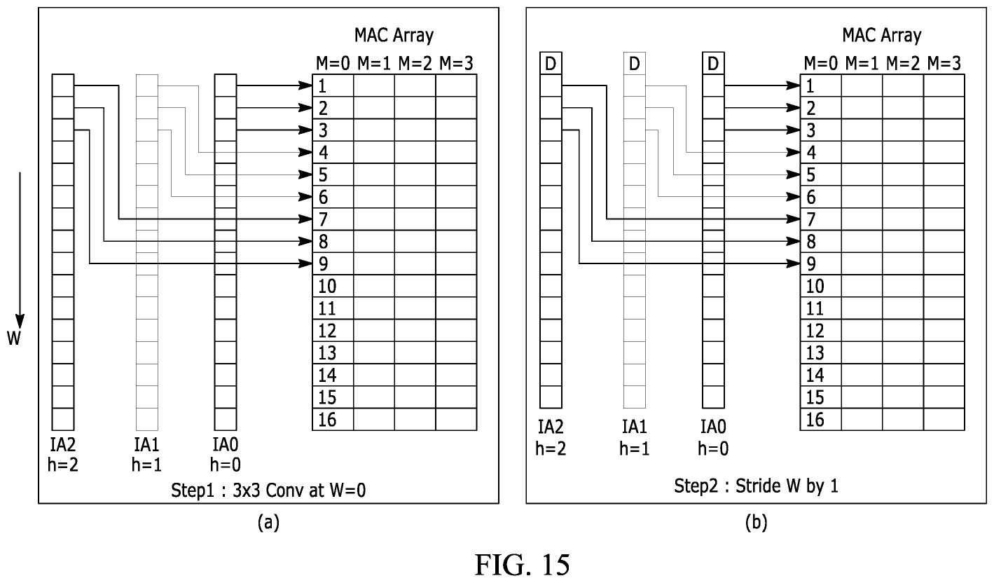

FIG. 15 illustrates an example MAC array optimized to handle 3×3 (RXS) convolutions with C=1. The proposed optimization may yield MAC compute utilization of 9/16. The MAC array could be optimized such that each M-lane has only RxS MAC cells instead of redundant cells shown above to achieve 100% utilization. Since the input channel C is one, each IA register holds a vector along a spatial dimension, indicated by h, in FIG. 15. Each IA register may hold the w values for each h dimension. Three input activation elements from 3 IA Vector registers may be broadcast to MAC arrays across all M lanes. The output produced in the MAC array is computed in a single step for covering the entire RxS filter spatial window, instead of iterating over multiple phases/steps.

In the example illustrated in FIG. 15, h=0 is loaded to IA0, h=1 is loaded to IA1, and h=2 is loaded to IA2. In step1, as illustrated in FIG. 15 (a), the output for the first spatial datapoint e,f=0,0 may be calculated as: Out[M][0][0]=W[M][0][0]*IA[0] [0]+W[M][0][1]*IA[0][1]+W[M][0]1[2]*IA[0][2]+W[M][1][0]*IA[1][0]+W[M][1][1]*IA[1][1]+W[M][1]1[2]*IA[1]1[2]+W[M][2][0]*IA[2][0]+W[M][2][1]*IA[2][1]+W[M][2][2]*IA[2][2].

In step2, the filter is moved to the right by its stride (1 in the example illustrated in FIG. 15). The same IA registers are reused but slid down (by reading different elements dictated by stride value) as shown in the FIG. 15 (b) and calculates the next output in spatial dimension.

These steps are repeated multiple times until all the values of IA0, IA1, and IA2 are exhausted. At this point a new set of IA values are loaded (possibly in parallel) representing another spatial tile of the input activation tensor and multiple compute steps are performed. This is repeated to complete the problem size of convolution.

### Accelerating Group-Wise Convolutions

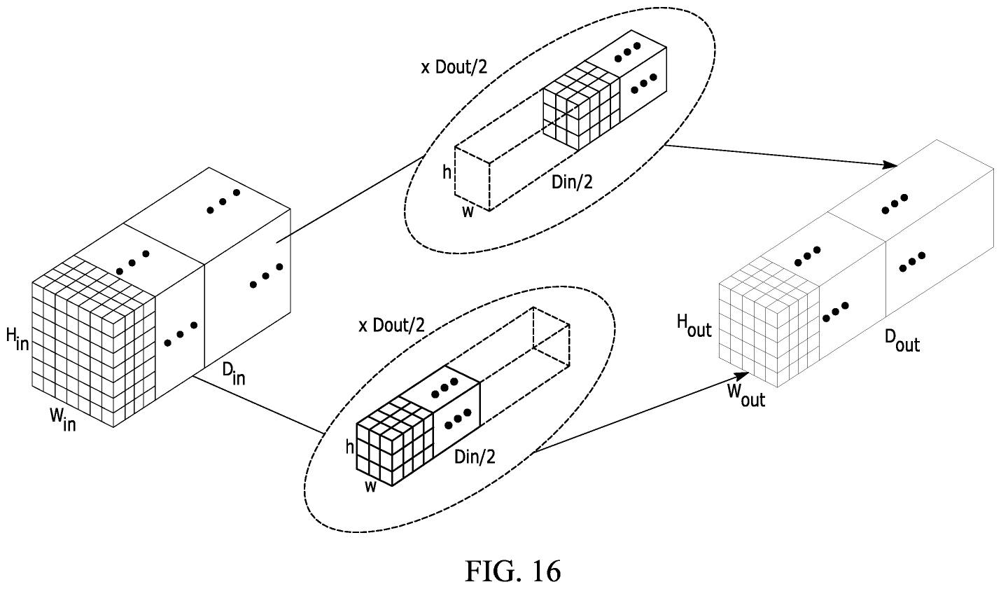

Group-wise convolutions were introduced to reduce computational complexity while dividing features into groups. Each group is expected to find out specific features from the network. These group features may be then combined to form a single and denser feature map. In group-wise convolution, many convolutions are done independently in groups of G1 input channels and G2 output channels, across a larger input tensor of C input channels and M output channels. Typically, G1=G2. FIG. 16 illustrates an example group-wise convolution with 2 filter groups. In each filter group, a number of channels (depth) of each filter is only half of that in the nominal 2D convolutions. The number of channels in each filer is C/2, wherein Din represents a number of input channels. Each filter group contains M/2 filters. The first filter group convolves with the first half of the input layer ([:,:, 0: C/2]), while the second filter group convolves with the second half of the input layer ([:,:, C/2: C]). As a result, each filter group creates M/2 channels. Overall, two groups create 2×M/2=M channels. These channels may be stacked in the output layer with M channels. Depth-wise convolutions is a specialized case of groups-wise convolutions where groups=number of input channels, so g1=g2=1.

The group-wise convolutions can be mapped to the MAC array illustrated in FIG. 6. However, if a size of each sub-group convolution is smaller than the MAC array size, the compute utilization would suffer. For example, if C and M is 64×64 and the convolution sub-group size is 8×8 (CxM per sub-group), the compute utilization would just be 8×8/64*64=1/64. Additionally, the inputs and outputs of the MAC array need to be padded with 0, costing memory transform cycles and storage.

In particular embodiments, a large MAC array may be fractured into smaller MAC arrays which can operate with independent data. All of the MAC sub-arrays may be fed from the same IA register and output to the output vector register array. However, the dataflow may be different from the architecture in FIG. 4.

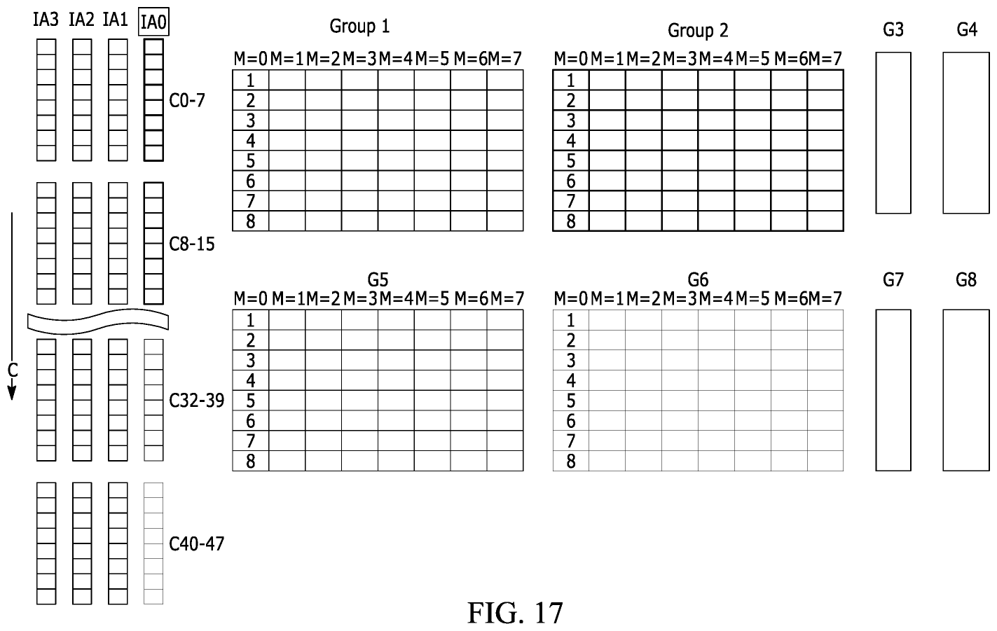

FIG. 17 illustrates an example MAC array that are fractured into smaller sub-arrays. The MAC array with 512 MAC units are fractured into sub-arrays optimized for 8 C per group. A total of 8 sub-arrays exist in the MAC array. Each of size 8×8 MACs are fed from different channels of the same IA vector. Each group is loaded with independent weights by software. For instance, the Group1 8×8 array is fed with the IA elements C0-7 which are broadcast across the 8 M lanes in this group. A vector of size 8 is produced by this group. Simultaneously the other groups are fed from the corresponding channels. The output vectors produced are concatenated and fed to the output vector register array.

The compute utilization of a convolution sub-group of size (8×8) would have been (8/32)*(8/16)=1/8 in a MAC array presented in FIG. 6 with C=32, M=16, would be improved to 100% with this proposal.

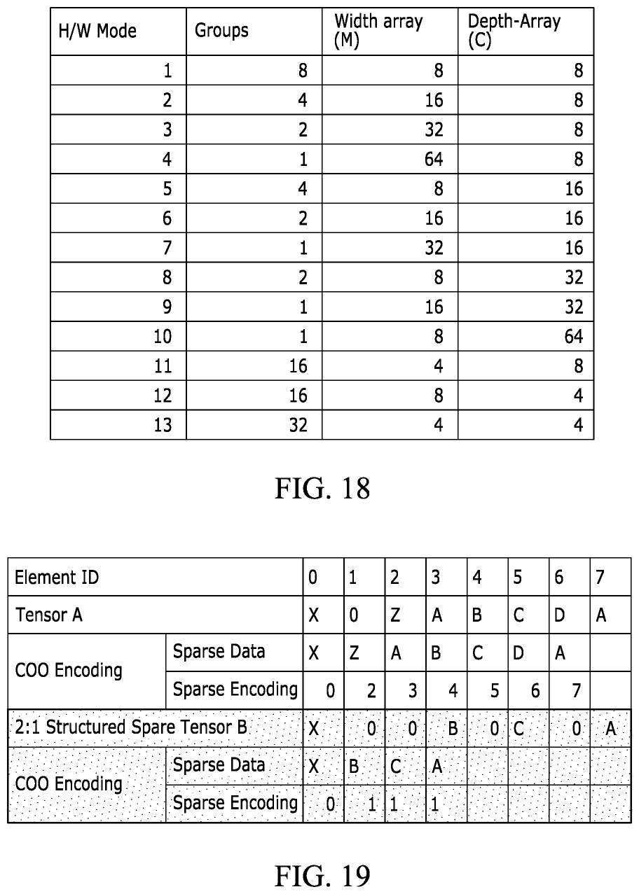

A MAC array could be modified to accommodate multiple group configurations, selectable runtime. FIG. 18 illustrates a list of example group configurations that can be supported by a MAC array with 512 MAC units. A right mode or array size could be chosen based on the convolution parameters by software to yield the best possible compute utilization. The key hardware element to achieve this reconfiguration may be the MUX structure between the MAC array and IA registers, which is included as part of the activation mux in FIG. 6.

Accelerating CNN with Sparse Tensors

Many ML computations may comprise matrix multiplications with sparce matrices or matrices comprising zeros. A sparce matrix is a matrix that is comprised of mostly zero values. These zeros can be compressed to save memory space and bandwidth required to fetch from higher levels of memory. Additionally, these zero values may be skipped during a matrix multiplication calculation to accelerate the computation and improve the hardware utilization defined as effective Multiply-Add/cycle. Accelerating the computation may also result in decreased latency and improved throughput.

A non-lossy optimization with a special hardware ISA and microarchitecture is proposed herein to opportunistically accelerate matrix multiplication/CNN computation with tensors with sparsity (0 numerical values) in the weight array. The proposed optimization may be a further enhancement to a fully-programmable SIMD VLIW CPUs/DSPs illustrated in FIG. 4. The data-flows and operating models described for the processor illustrated in FIG. 4 may still apply. The only difference may be a manner of handling of sparse tensors. Additionally, the optimizations illustrated in FIGS. 13-18 may apply on top of the proposed optimization to enable sparse tensor acceleration for depth-wise, C=1 and groupwise convolution layers.

FIG. 19 illustrates an example table illustrating sparse tensor encodings. A first tensor, tensor A, illustrated in FIG. 19 comprises 8 elements, among which the second element, element ID 1, has zero value. Such tensors may be compressed in many different formats by eliminating the storage of 0 valued data and saving memory. For example, the table in FIG. 19 illustrates coordinate list (COO) compression where only non-zero elements are preserved (Sparse-Data) along with a Sparse encoding capturing the element index corresponding to each non-zero Data. Sparse encoding may be used to identify the position of the corresponding non-zero sparse data in an uncompressed/dense array. The sparse patterns may dictate the efficiency/compression achieved by sparse encoding algorithms.

The shaded portion of the table in FIG. 19 illustrates a constrained form of sparsity called structured sparsity. In this example, only one out of every two consecutive elements may be non-zero. This constraint may help in decreasing the number of bytes consumed by the Sparse Encodings as shown in the example in FIG. 19.

ML tensors may be optimized to have only N non-zero values out of every M consecutive dense values. Those tensors may be referred to as M:N structured sparse tensors. The table in FIG. 19 illustrates a 2:1 case, where out of every 2 dense values only 1 value is non-zero. The encoding for each sparse data of M:N structured sparse tensors may require N*log 2(M) bits. For 2:1 structured sparse tensor, each sparse encoding needs log 2(2)*1, which is 1 bit. Structured sparsity can be induced in matrix multiplications/CNNs and many ML algorithms in the process of training, called pruning.

In particular embodiments, hardware architectures and methods may be used to skip computations involving zero values by leveraging sparsity in a weight tensor stored in a modified weight vector register array. Input activation tensor in the input activation vector register array may be assumed to be dense. Thus, sparsity or zero-skipping may not be leveraged even if the input activation tensor is sparse. The sparse structure supported may be hardened. A hardware architecture may be capable of handling one of many M:N configurations. In particular embodiments, an algorithm may map an input activation tensor to the weight vector register array 460 and map the weight tensor to the input activation vector register array if the input activation tensor is a structured sparse tensor. Special ISA instructions may be introduced to support the hardware architectures introduced to support structured sparse matrix multiplication accelerations.

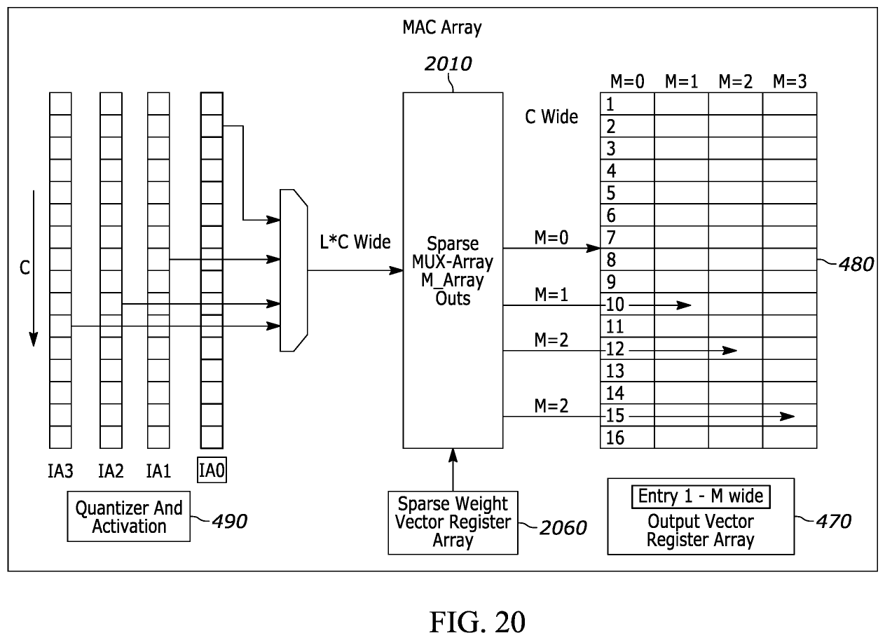

FIG. 20 illustrates an example hardware architecture optimization to support a structured sparse matrix multiplication acceleration. A sparse MUX array 2010 and a sparse weight vector register array 2060 may be key new components for the structure sparse matrix multiplication acceleration. The sparse weight vector register array 2060 may be fed with only non-zero elements of the weight tensor. The sparse weight vector register array 2060 may also store sparsity encodings. In particular embodiments, the sparse weight vector register array 2060 may comprise two parts: a first register array for storing the non-zero elements of the weight tensor and a second register array for storing sparsity encodings. The first register array may be an existing dense weight vector register array 460. Input activation elements corresponding to the non-zero elements of the weight tensor may be dynamically selected by the sparse MUX array 2010. Computations involving the zero-valued weight elements may be skipped.

In the base architecture illustrated in FIG. 6, the input activation vector register array may be read at C width to feed the MAC array 480, where C is a number of input channels. With the sparse matrix multiplication acceleration architecture illustrated in FIG. 20, the input activation vector register array may need to be read at a higher interface width of L*C due to higher bandwidth, where L=ceiling(M/N), where M and N are parameters of M:N structured-sparsity.

In particular embodiments, the sparse weight vector register array 2060 may be used to store the structured sparse encodings. The number of encoding bits required per MAC-cell or weight register may be N*log 2(M) bits. The sparse weight vector register array 2060 may be used to feed the control lines of the sparse MUX Array 2010 to provide pointers to the input activation elements that need to be routed to each MAC unit in the MAC Array 480.

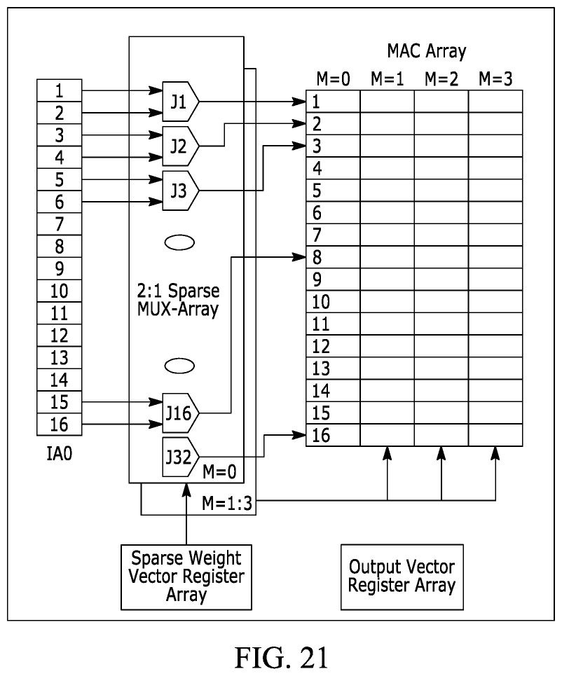

In particular embodiments, the sparse MUX array 2010 may be an array of MUXs to route a corresponding input activation scalar value to each MAC unit. The number of MUXs may be equal to the number of MAC units. FIG. 21 illustrates an example architecture diagram of a sparse MUX array for 2:1 sparse weight tensor. The sparse MUX array may feed separate vectors of C to each of M lanes of the MAC array 480. Each MUX J1-J32 for M=0 output lane may be fed with 2 consecutive input activation values. M sets of those MUXs for the entire MAC Array 480 may exist in the sparse MUX array 2010 because different input activation elements may correspond to non-zero elements in each weight vector in the sparse weight vector register array 2060. For example, J1 is fed with IA[1], IA[2]; J8 is fed with IA[15],IA[16] and so on. The control line for J1 may be fed with bit0 of the sparse weight vector register array 2060 (1 bit per MUX for 2:1 structure sparsity). Likewise, J2 may be fed with bit1, and J32 may be fed with bit32. With a 2:1 sparse weight tensor, two input activation vectors may be multiplied to a compressed weight vector in the sparse weight vector register array 2060. A size of each 2:1 compressed weight vector may be C/2, where C is a number of input channels.

In particular embodiments, selecting between various sparse mode and regular dense modes may be accomplished by setting global state registers in the processor ISA. The Sparse Weight states and logic in sparse MUX array 2010 may be bypassed in regular dense modes.

This optimized MAC array extensions for structured sparsity may be incorporated into VLIW SIMD DSP/CPU as specialized ISA. With the aid of these optimizations, sparse matrices can be accelerated by a factor of M/N, in addition to the benefits of memory and bandwidth savings due to structure spare compression.

### Systems and Methods

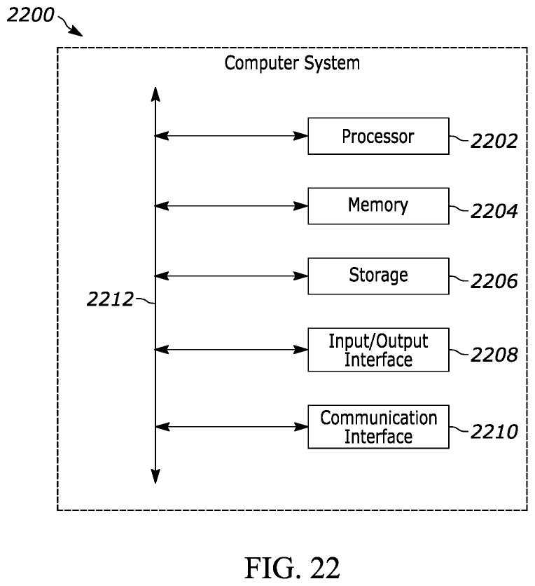

FIG. 22 illustrates an example computer system 2200. In particular embodiments, one or more computer systems 2200 perform one or more steps of one or more methods described or illustrated herein. In particular embodiments, one or more computer systems 2200 provide functionality described or illustrated herein. In particular embodiments, software running on one or more computer systems 2200 performs one or more steps of one or more methods described or illustrated herein or provides functionality described or illustrated herein. Particular embodiments include one or more portions of one or more computer systems 2200. Herein, reference to a computer system may encompass a computing device, and vice versa, where appropriate. Moreover, reference to a computer system may encompass one or more computer systems, where appropriate.

This disclosure contemplates any suitable number of computer systems 2200. This disclosure contemplates computer system 2200 taking any suitable physical form. As example and not by way of limitation, computer system 2200 may be an embedded computer system, a system-on-chip (SOC), a single-board computer system (SBC) (such as, for example, a computer-on-module (COM) or system-on-module (SOM)), a desktop computer system, a laptop or notebook computer system, an interactive kiosk, a mainframe, a mesh of computer systems, a mobile telephone, a personal digital assistant (PDA), a server, a tablet computer system, or a combination of two or more of these. Where appropriate, computer system 2200 may include one or more computer systems 2200; be unitary or distributed; span multiple locations; span multiple machines; span multiple data centers; or reside in a cloud, which may include one or more cloud components in one or more networks. Where appropriate, one or more computer systems 2200 may perform without substantial spatial or temporal limitation one or more steps of one or more methods described or illustrated herein. As an example and not by way of limitation, one or more computer systems 2200 may perform in real time or in batch mode one or more steps of one or more methods described or illustrated herein. One or more computer systems 2200 may perform at different times or at different locations one or more steps of one or more methods described or illustrated herein, where appropriate.

In particular embodiments, computer system 2200 includes a processor 2202, memory 2204, storage 2206, an input/output (I/O) interface 2208, a communication interface 2210, and a bus 2212. Although this disclosure describes and illustrates a particular computer system having a particular number of particular components in a particular arrangement, this disclosure contemplates any suitable computer system having any suitable number of any suitable components in any suitable arrangement.

In particular embodiments, processor 2202 includes hardware for executing instructions, such as those making up a computer program. As an example and not by way of limitation, to execute instructions, processor 2202 may retrieve (or fetch) the instructions from an internal register, an internal cache, memory 2204, or storage 2206; decode and execute them; and then write one or more results to an internal register, an internal cache, memory 2204, or storage 2206. In particular embodiments, processor 2202 may include one or more internal caches for data, instructions, or addresses. This disclosure contemplates processor 2202 including any suitable number of any suitable internal caches, where appropriate. As an example and not by way of limitation, processor 2202 may include one or more instruction caches, one or more data caches, and one or more translation lookaside buffers (TLBs). Instructions in the instruction caches may be copies of instructions in memory 2204 or storage 2206, and the instruction caches may speed up retrieval of those instructions by processor 2202. Data in the data caches may be copies of data in memory 2204 or storage 2206 for instructions executing at processor 2202 to operate on; the results of previous instructions executed at processor 2202 for access by subsequent instructions executing at processor 2202 or for writing to memory 2204 or storage 2206; or other suitable data. The data caches may speed up read or write operations by processor 2202. The TLBs may speed up virtual-address translation for processor 2202. In particular embodiments, processor 2202 may include one or more internal registers for data, instructions, or addresses. This disclosure contemplates processor 2202 including any suitable number of any suitable internal registers, where appropriate. Where appropriate, processor 2202 may include one or more arithmetic logic units (ALUs); be a multi-core processor; or include one or more processors 2202. Although this disclosure describes and illustrates a particular processor, this disclosure contemplates any suitable processor.

In particular embodiments, memory 2204 includes main memory for storing instructions for processor 2202 to execute or data for processor 2202 to operate on. As an example and not by way of limitation, computer system 2200 may load instructions from storage 2206 or another source (such as, for example, another computer system 2200) to memory 2204. Processor 2202 may then load the instructions from memory 2204 to an internal register or internal cache. To execute the instructions, processor 2202 may retrieve the instructions from the internal register or internal cache and decode them. During or after execution of the instructions, processor 2202 may write one or more results (which may be intermediate or final results) to the internal register or internal cache. Processor 2202 may then write one or more of those results to memory 2204. In particular embodiments, processor 2202 executes only instructions in one or more internal registers or internal caches or in memory 2204 (as opposed to storage 2206 or elsewhere) and operates only on data in one or more internal registers or internal caches or in memory 2204 (as opposed to storage 2206 or elsewhere). One or more memory buses (which may each include an address bus and a data bus) may couple processor 2202 to memory 2204. Bus 2212 may include one or more memory buses, as described below. In particular embodiments, one or more memory management units (MMUs) reside between processor 2202 and memory 2204 and facilitate accesses to memory 2204 requested by processor 2202. In particular embodiments, memory 2204 includes random access memory (RAM). This RAM may be volatile memory, where appropriate. Where appropriate, this RAM may be dynamic RAM (DRAM) or static RAM (SRAM). Moreover, where appropriate, this RAM may be single-ported or multi-ported RAM. This disclosure contemplates any suitable RAM. Memory 2204 may include one or more memories 2204, where appropriate. Although this disclosure describes and illustrates particular memory, this disclosure contemplates any suitable memory.

In particular embodiments, storage 2206 includes mass storage for data or instructions. As an example and not by way of limitation, storage 2206 may include a hard disk drive (HDD), a floppy disk drive, flash memory, an optical disc, a magneto-optical disc, magnetic tape, or a Universal Serial Bus (USB) drive or a combination of two or more of these. Storage 2206 may include removable or non-removable (or fixed) media, where appropriate. Storage 2206 may be internal or external to computer system 2200, where appropriate. In particular embodiments, storage 2206 is non-volatile, solid-state memory. In particular embodiments, storage 2206 includes read-only memory (ROM). Where appropriate, this ROM may be mask-programmed ROM, programmable ROM (PROM), erasable PROM (EPROM), electrically erasable PROM (EEPROM), electrically alterable ROM (EAROM), or flash memory or a combination of two or more of these. This disclosure contemplates mass storage 2206 taking any suitable physical form. Storage 2206 may include one or more storage control units facilitating communication between processor 2202 and storage 2206, where appropriate. Where appropriate, storage 2206 may include one or more storages 2206. Although this disclosure describes and illustrates particular storage, this disclosure contemplates any suitable storage.

In particular embodiments, I/O interface 2208 includes hardware, software, or both, providing one or more interfaces for communication between computer system 2200 and one or more I/O devices. Computer system 2200 may include one or more of these I/O devices, where appropriate. One or more of these I/O devices may enable communication between a person and computer system 2200. As an example and not by way of limitation, an I/O device may include a keyboard, keypad, microphone, monitor, mouse, printer, scanner, speaker, still camera, stylus, tablet, touch screen, trackball, video camera, another suitable I/O device or a combination of two or more of these. An I/O device may include one or more sensors. This disclosure contemplates any suitable I/O devices and any suitable I/O interfaces 2208 for them. Where appropriate, I/O interface 2208 may include one or more device or software drivers enabling processor 2202 to drive one or more of these I/O devices. I/O interface 2208 may include one or more I/O interfaces 2208, where appropriate. Although this disclosure describes and illustrates a particular I/O interface, this disclosure contemplates any suitable I/O interface.

In particular embodiments, communication interface 2210 includes hardware, software, or both providing one or more interfaces for communication (such as, for example, packet-based communication) between computer system 2200 and one or more other computer systems 2200 or one or more networks. As an example and not by way of limitation, communication interface 2210 may include a network interface controller (NIC) or network adapter for communicating with an Ethernet or other wire-based network or a wireless NIC (WNIC) or wireless adapter for communicating with a wireless network, such as a WI-FI network. This disclosure contemplates any suitable network and any suitable communication interface 2210 for it. As an example and not by way of limitation, computer system 2200 may communicate with an ad hoc network, a personal area network (PAN), a local area network (LAN), a wide area network (WAN), a metropolitan area network (MAN), or one or more portions of the Internet or a combination of two or more of these. One or more portions of one or more of these networks may be wired or wireless. As an example, computer system 2200 may communicate with a wireless PAN (WPAN) (such as, for example, a BLUETOOTH WPAN), a WI-FI network, a WI-MAX network, a cellular telephone network (such as, for example, a Global System for Mobile Communications (GSM) network), or other suitable wireless network or a combination of two or more of these. Computer system 2200 may include any suitable communication interface 2210 for any of these networks, where appropriate. Communication interface 2210 may include one or more communication interfaces 2210, where appropriate. Although this disclosure describes and illustrates a particular communication interface, this disclosure contemplates any suitable communication interface.

In particular embodiments, bus 2212 includes hardware, software, or both coupling components of computer system 2200 to each other. As an example and not by way of limitation, bus 2212 may include an Accelerated Graphics Port (AGP) or other graphics bus, an Enhanced Industry Standard Architecture (EISA) bus, a front-side bus (FSB), a HYPERTRANSPORT (HT) interconnect, an Industry Standard Architecture (ISA) bus, an INFINIBAND interconnect, a low-pin-count (LPC) bus, a memory bus, a Micro Channel Architecture (MCA) bus, a Peripheral Component Interconnect (PCI) bus, a PCI-Express (PCIe) bus, a serial advanced technology attachment (SATA) bus, a Video Electronics Standards Association local (VLB) bus, or another suitable bus or a combination of two or more of these. Bus 2212 may include one or more buses 2212, where appropriate. Although this disclosure describes and illustrates a particular bus, this disclosure contemplates any suitable bus or interconnect.

Herein, a computer-readable non-transitory storage medium or media may include one or more semiconductor-based or other integrated circuits (ICs) (such, as for example, field-programmable gate arrays (FPGAs) or application-specific ICs (ASICs)), hard disk drives (HDDs), hybrid hard drives (HHDs), optical discs, optical disc drives (ODDs), magneto-optical discs, magneto-optical drives, floppy diskettes, floppy disk drives (FDDs), magnetic tapes, solid-state drives (SSDs), RAM-drives, SECURE DIGITAL cards or drives, any other suitable computer-readable non-transitory storage media, or any suitable combination of two or more of these, where appropriate. A computer-readable non-transitory storage medium may be volatile, non-volatile, or a combination of volatile and non-volatile, where appropriate.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, feature, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative. Additionally, although this disclosure describes or illustrates particular embodiments as providing particular advantages, particular embodiments may provide none, some, or all of these advantages.

What is claimed is:

1. A system comprising:
a processor comprising:
an internal memory;
a Multiply-Accumulate (MAC) array;
a first vector register array communicatively connected to the MAC array through a multiplexer (MUX);
a second vector register array communicatively connected to the MAC array; and
a third vector register array communicatively connected to the MAC array; and
a non-transitory memory coupled to the processor comprising instructions executable by the processor, the processor operable when executing a first instruction among the instructions to:
feed a weight vector array from the second vector register array to the MAC array;
broadcast an input activation vector to the MAC array, wherein the input activation vector is selected by the MUX from the first vector register array based on the first instruction;
multiply, at each MAC unit in the MAC array, an input activation value broadcast to the MAC unit from the input activation vector and a weight value fed to the MAC unit from the weight vector array; and
store a partial output activation vector to the third vector register array, wherein the partial output activation vector is the output of the MAC array.

2. The system of claim 1, wherein the processor is further operable when executing a second instruction among the instructions to:
load an input activation vector from the internal memory to a vector register indicated by the second instruction among the first vector register array, wherein a location of the input activation vector in the internal memory is indicated by the second instruction.

3. The system of claim 1, wherein the processor is further operable when executing a third instruction among the instructions to:
load a weight vector from the internal memory to a vector register indicated by the third instruction among the second vector register array, wherein a location of the weight vector in the internal memory is indicated by the third instruction.

4. The system of claim 1, wherein the processor is further operable when executing a fourth instruction among the instructions to:
quantize n-bit numbers in a vector register among the third vector register array to m-bit numbers based on quantization parameters stored in a corresponding vector register designated for the quantization parameters; and
perform a non-linear operation on the quantized m-bit numbers.

5. The system of claim 4, wherein m is configurable.

6. The system of claim 1, wherein the processor is a very large instruction word (VLIW) processor comprising a plurality of function units, and wherein the instructions are performed simultaneously in the plurality of function units.

7. The system of claim 1, wherein an instruction set architecture (ISA) of the processor supports hardware instructions associated with hardware components of the processor including the internal memory, the MAC array, the first vector register array, the second vector register array, and the third vector register array.

8. The system of claim 1, wherein the instructions are single instruction multiple data (SIMD) instructions, each of which processes a fixed-size vector data.

9. The system of claim 1, wherein a shape of the MAC array is dynamically configured at runtime based on hardware configuration parameters stored in a register array designated for the hardware configuration parameters.

10. The system of claim 9, wherein the shape of the MAC array is configured to C-by-M, wherein C is a number of input channels in the input activation vector, wherein M is a number of filters used for convolution operations.

11. The system of claim 10, wherein C and M are configurable.

12. The system of claim 1, wherein the input activation vector comprises C input activation values corresponding to a pixel element within an input activation tensor, wherein C is a number of input channels.

13. The system of claim 12, wherein each weight vector in the weight vector array comprises C weight values, wherein the weight vector array comprises a filter element at a position of M filters.

14. The system of claim 13, wherein the processor is further operable when executing the first instruction to:
generate, for each of the M filters, an output activation value by accumulating outputs of MAC units corresponding to the filter, wherein the output activation vector comprises M output activation values.

15. The system of claim 1, wherein storing the partial output activation vector to the third vector register array comprises overwriting residual values of the vector register with values of the partial output activation vector.

16. The system of claim 1, wherein storing the partial output activation vector to the third vector register array comprises accumulating values of the partial output activation vector to residual values of the vector register.

17. A method comprising, by a system comprising a processor and a non-transitory memory coupled to the processor comprising instructions executable by the processor, wherein the processor comprises an internal memory; a Multiply-Accumulate (MAC) array; a first vector register array communicatively connected to the MAC array through a multiplexer (MUX); a second vector register array communicatively connected to the MAC array; and a third vector register array communicatively connected to the MAC array:
feeding a weight vector array from the second vector register array to the MAC array;
broadcasting an input activation vector to the MAC array, wherein the input activation vector is selected by the MUX from the first vector register array based on a first instruction;
multiplying, at each MAC unit in the MAC array, an input activation value broadcast to the MAC unit from the input activation vector and a weight value fed to the MAC unit from the weight vector array; and
storing a partial output activation vector to the third vector register array, wherein the partial output activation vector is the output of the MAC array.

18. The method of claim 17, further comprising:
loading an input activation vector from the internal memory to a vector register indicated by the second instruction among the first vector register array, wherein a location of the input activation vector in the internal memory is indicated by the second instruction.

19. The method of claim 17, further comprising:
loading a weight vector from the internal memory to a vector register indicated by the third instruction among the second vector register array, wherein a location of the weight vector in the internal memory is indicated by the third instruction.

20. One or more computer-readable non-transitory storage media embodying software that is operable when executed by a processor to, wherein the processor comprises an internal memory; a Multiply-Accumulate (MAC) array; a first vector register array communicatively connected to the MAC array through a multiplexer (MUX); a second vector register array communicatively connected to the MAC array; and a third vector register array communicatively connected to the MAC array:
feed a weight vector array from the second vector register array to the MAC array;
broadcast an input activation vector to the MAC array, wherein the input activation vector is selected by the MUX from the first vector register array based on a first instruction;
multiply, at each MAC unit in the MAC array, an input activation value broadcast to the MAC unit from the input activation vector and a weight value fed to the MAC unit from the weight vector array; and
store a partial output activation vector to the third vector register array, wherein the partial output activation vector is the output of the MAC array.
